(19) United States
(12) Patent Application Publication
(10) Pub. No.: US 2025/0194280 A1
(43) Pub. Date: Jun. 12, 2025

(54) PHOTODETECTION DEVICE AND ELECTRONIC APPARATUS

(71) Applicant: SONY SEMICONDUCTOR SOLUTIONS CORPORATION, Kanagawa (JP)

(72) Inventor: Mikinori ITO, Kanagawa (JP)

(73) Assignee: SONY SEMICONDUCTOR SOLUTIONS CORPORATION, Kanagawa (JP)

(21) Appl. No.: 18/846,517

(22) PCT Filed: Feb. 17, 2023
(86) PCT No.: PCT/JP2023/005824

§ 371 Date: Sep. 12, 2024

(30) Foreign Application Priority Data
Mar. 31, 2022 (JP) 2022-059358

(51) Int. Cl. H10F 39/00; H10F 39/18

(52) U.S. Cl. CPC H10F 39/807; H10F 39/8023; H10F 39/8033; H10F 39/8057; H10F 39/18

(57) ABSTRACT

Provided is a photodetection device capable of maintaining a saturation signal amount of one photodiode and avoiding deterioration of electronic readout in a case of forming a dual photodiode. A photodetection device includes a semiconductor layer in which a plurality of pixels is arranged in a matrix and which has a light incident surface. Each of the plurality of pixels includes an inter-pixel separation section, an intra-pixel separation section, a first photoelectric conversion section and a second photoelectric conversion section, a first transfer transistor, and a second transfer transistor. The first photoelectric conversion section and the second photoelectric conversion section are provided adjacent to each other via the intra-pixel separation section in plan view. The vertical gate electrodes of the first and second transfer transistors are arranged along a diagonal line connecting two corner portions of the pixels across the intra-pixel separation section in plan view.

### TECHNICAL FIELD

The present disclosure relates to a photodetection device and an electronic apparatus including the photodetection device.

### BACKGROUND ART

Conventionally, in an electronic apparatus having an imaging function such as a digital still camera or a digital video camera, for example, a solid-state imaging element such as a charge coupled device (CCD) or a complementary metal oxide semiconductor (CMOS) image sensor is used as a photodetection device. The photodetection device includes a pixel in which a photodiode (photoelectric conversion element) that performs photoelectric conversion and a transistor are combined, and an image is constructed on the basis of pixel signals output from a plurality of pixels arranged in a plane.

For example, in a solid-state imaging element, charges accumulated in a photodiode are transferred to a floating diffusion (FD) section having a predetermined capacitance provided in a connection portion between the photodiode and a gate electrode of an amplification transistor. Then, a pixel signal corresponding to the amount of electric charge accumulated in the FD portion is read from the pixel, subjected to analog digital (AD) conversion by an AD conversion circuit including a comparator, and output.

Furthermore, in recent years, a technology for detecting a phase using a part of pixels of a CMOS image sensor and improving autofocus (AF) speed, so-called image plane phase difference AF, has become widespread. In the image plane phase difference AF, a photodiode included in a pixel is divided into a plurality of photodiodes, phase information is generated on the basis of a pixel signal obtained by each divided photodiode, and distance measurement is performed on the basis of the phase information.

Meanwhile, in a case where strong light is incident on a pixel, a phenomenon called color mixing may occur in which charges accumulated in a photodiode of the pixel are saturated and overflow, and leak to an adjacent pixel. Therefore, a solid-state imaging element has been proposed in which an inter-pixel separation section that separates pixels is configured by a full trench (FFTI) (for example, Patent Document 1).

### CITATION LIST

### Patent Document

Patent Document 1: WO 2017/130723 A

### SUMMARY OF THE INVENTION

### Problems to be Solved by the Invention

By the way, even in the solid-state imaging element described in Patent Document 1, in a case where a dual photodiode including a first photodiode and a second photodiode is formed with a vertical gate electrode (VG) of a transfer transistor, there is a risk that a left-right potential between the first photodiode and the second photodiode is modulated at the time of single pixel reading and a saturation signal amount of one photodiode decreases, and there is a risk that a left-right potential becomes too deep at the time of LR (left-right) addition reading and electronic readout deteriorates.

The present disclosure has been made in view of such circumstances, and an object of the present disclosure is to provide a photodetection device and an electronic apparatus capable of maintaining a saturation signal amount of one photodiode and avoiding deterioration of electronic readout in a case of forming a dual photodiode.

### Solutions to Problems

One aspect of the present disclosure is a photodetection device including a semiconductor layer including a plurality of pixels arranged in a matrix and having a light incident surface on which light is incident on the pixels, each of the plurality of pixels including: an inter-pixel separation section that defines an outer edge shape of the pixel, is formed by a full trench extending from a light incident surface of the semiconductor layer to an element surface on a side opposite to the light incident surface, and insulates and shields the pixel adjacent; an intra-pixel separation section that separates the pixel into two; a first photoelectric conversion section and a second photoelectric conversion section that are provided adjacent to each other via the intra-pixel separation section in plan view and generate a charge of an amount corresponding to light incident on the light incident surface, respectively; a plurality of floating diffusion regions provided on the element surface of the semiconductor layer and temporarily accumulating the charge; a first transfer transistor that transfers the charge generated by the first photoelectric conversion section to one of the plurality of floating diffusion regions; and a second transfer transistor that transfers the charge generated by the second photoelectric conversion section to another one of the floating diffusion regions, in which the outer edge shape of the pixel is a geometric shape including at least four or more sides in plan view, and a vertical gate electrode of the first transfer transistor and a vertical gate electrode of the second transfer transistor are arranged along a diagonal line connecting two corner portions of the pixels across the intra-pixel separation section in the plan view.

Another aspect of the present disclosure is an electronic apparatus including a photodetection device including a semiconductor layer including a plurality of pixels arranged in a matrix and having a light incident surface on which light is incident on the pixels, each of the plurality of pixels including: an inter-pixel separation section that defines an outer edge shape of the pixel, is formed by a full trench extending from a light incident surface of the semiconductor layer to an element surface on a side opposite to the light incident surface, and insulates and shields the pixel adjacent; an intra-pixel separation section that separates the pixel into two; a first photoelectric conversion section and a second photoelectric conversion section that are provided adjacent to each other via the intra-pixel separation section in plan view and generate a charge of an amount corresponding to light incident on the light incident surface, respectively; a plurality of floating diffusion regions provided on the element surface of the semiconductor layer and temporarily accumulating the charge; a first transfer transistor that transfers the charge generated by the first photoelectric conversion section to one of the plurality of floating diffusion regions; and a second transfer transistor that transfers the charge generated by the second photoelectric conversion section to another one of the floating diffusion regions, in which the outer edge shape of the pixel is a geometric shape including at least four or more sides in plan view, and a vertical gate electrode of the first transfer transistor and a vertical gate electrode of the second transfer transistor are arranged along a diagonal line connecting two corner portions of the pixels across the intra-pixel separation section in the plan view.

### BRIEF DESCRIPTION OF DRAWINGS

FIG. 1 is a chip layout diagram illustrating a configuration example of a photodetection device according to a first embodiment of the present disclosure.

FIG. 2 is a block diagram illustrating a configuration example of the photodetection device according to the first embodiment of the present disclosure.

FIG. 3 is an equivalent circuit diagram of a pixel of the photodetection device according to the first embodiment of the present disclosure.

FIG. 4 is a partial longitudinal cross-sectional view illustrating an example of a laminated structure of the photodetection device according to the first embodiment of the present disclosure.

FIG. 5 is a transverse cross-sectional view illustrating a relative relationship between respective configurations when a pixel in a comparative example is viewed in cross section on a first surface.

FIG. 6 is a schematic diagram illustrating a relationship between potential distributions of components in A1-A2 in FIG. 5.

FIG. 7 is a transverse cross-sectional view illustrating a relative relationship between respective configurations when a pixel in the first embodiment of the present disclosure is viewed in a cross section in a first surface.

FIG. 8 is a schematic diagram illustrating a relationship between potential distributions of components in A3-A4 in FIG. 7.

FIG. 9 is a plan view illustrating an arrangement relationship of a plurality of pixels of a photodetection device according to the first embodiment of the present disclosure.

FIG. 10 is a plan view illustrating an arrangement relationship of a plurality of pixels of a photodetection device according to a first modification of the first embodiment of the present disclosure.

FIG. 11 is a plan view illustrating an arrangement relationship of a plurality of pixels of a photodetection device according to a second modification of the first embodiment of the present disclosure.

FIG. 12 is a plan view illustrating an arrangement relationship of a plurality of pixels of a photodetection device according to a third modification of the first embodiment of the present disclosure.

FIG. 13 is a plan view illustrating an arrangement relationship of a plurality of pixels of a photodetection device according to a fourth modification of the first embodiment of the present disclosure.

FIG. 14 is a plan view illustrating an arrangement relationship of a plurality of pixels of a photodetection device according to a second embodiment of the present disclosure.

FIG. 15 is a plan view illustrating an arrangement relationship of a plurality of pixels of a photodetection device according to a first modification of the second embodiment of the present disclosure.

FIG. 16 is a plan view illustrating an arrangement relationship of a plurality of pixels of a photodetection device according to a second modification of the second embodiment of the present disclosure.

FIG. 17 is a plan view illustrating an arrangement relationship of a plurality of pixels of a photodetection device according to a third modification of the second embodiment of the present disclosure.

FIG. 18 is a plan view illustrating an arrangement relationship of a plurality of pixels of a photodetection device according to a fourth modification of the second embodiment of the present disclosure.

FIG. 19 is a plan view illustrating an arrangement relationship of a plurality of pixels of a photodetection device according to a third embodiment of the present disclosure.

FIG. 20 is a plan view illustrating an arrangement relationship of a plurality of pixels of a photodetection device according to a first modification of the third embodiment of the present disclosure.

FIG. 21 is a plan view illustrating an arrangement relationship of a plurality of pixels of a photodetection device according to a second modification of the third embodiment of the present disclosure.

FIG. 22 is a plan view illustrating an arrangement relationship of a plurality of pixels of a photodetection device according to a third modification of the third embodiment of the present disclosure.

FIG. 23 is a plan view illustrating an arrangement relationship of a plurality of pixels of a photodetection device according to a fourth modification of the third embodiment of the present disclosure.

FIG. 24A is a plan view illustrating an arrangement relationship of a plurality of pixels of a photodetection device according to a fourth embodiment of the present disclosure.

FIG. 24B is a partial longitudinal cross-sectional view illustrating an example of a laminated structure of the photodetection device taken along an imaginary line B1-B2 illustrated in FIG. 24A. FIG. 24 is a plan view illustrating an arrangement relationship of a plurality of pixels of a photodetection device according to a fourth embodiment of the present disclosure.

FIG. 25 is a plan view illustrating an arrangement relationship of a plurality of pixels of a photodetection device according to a first modification of the fourth embodiment of the present disclosure.

FIG. 26 is a plan view illustrating an arrangement relationship of a plurality of pixels of a photodetection device according to a second modification of the fourth embodiment of the present disclosure.

FIG. 27 is a plan view illustrating an arrangement relationship of a plurality of pixels of a photodetection device according to a third modification of the fourth embodiment of the present disclosure.

FIG. 28 is a plan view illustrating an arrangement relationship of a plurality of pixels of a photodetection device according to a fourth modification of the fourth embodiment of the present disclosure.

FIG. 29 is a plan view illustrating an arrangement relationship of a plurality of pixels of a photodetection device according to a fifth embodiment of the present disclosure.

FIG. 30 is a plan view illustrating an arrangement relationship of a plurality of pixels of a photodetection device according to a first modification of the fifth embodiment of the present disclosure.

FIG. 31 is a plan view illustrating an arrangement relationship of a plurality of pixels of a photodetection device according to a second modification of the fifth embodiment of the present disclosure.

FIG. 32 is a plan view illustrating an arrangement relationship of a plurality of pixels of a photodetection device according to a third modification of the fifth embodiment of the present disclosure.

FIG. 33 is a plan view illustrating an arrangement relationship of a plurality of pixels of a photodetection device according to a fourth modification of the fifth embodiment of the present disclosure.

FIG. 34 is a block diagram illustrating a configuration example of an imaging device as an electronic apparatus to which the present technology is applied.

FIG. 35 is a block diagram depicting an example of schematic configuration of a vehicle control system.

FIG. 36 is a diagram of assistance in explaining an example of installation positions of an outside-vehicle information detecting section and an imaging section.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs to avoid the description from being redundant. However, it should be noted that the drawings are schematic, and the relationship between thickness and planar dimension, the ratio of thickness of each device or each member, and the like differ from actual ones. Therefore, specific thicknesses and dimensions should be determined in consideration of the following description. Furthermore, it is needless to say that the drawings include portions having different dimensional relationships and ratios.

In the present specification, a “first conductivity type” means one of a p-type or an n-type, and a “second conductivity type” means one of the p-type or the n-type different from the “first conductivity type”. Furthermore, “n” or “p” to which “+” or “−” is added means a semiconductor region having a relatively higher or lower impurity density than that of a semiconductor region to which “+” or “−” is not added. However, even in the semiconductor regions to which the same “n” and “n” are added, it does not mean that the impurity densities of the semiconductor regions are exactly the same.

Furthermore, definition of directions such as upward and downward directions, and the like in the following description is merely the definition for convenience of description, and does not limit the technical idea of the present disclosure. For example, it goes without saying that if a target is observed while being rotated by 90°, the upward and downward directions are converted into rightward and leftward directions, and if the target is observed while being rotated by 180°, the upward and downward directions are inverted.

Note that the effects described in the present specification are merely examples and are not limited, and other effects may be provided.

### First Embodiment

In the first embodiment, an example in which the present technology is applied to a photodetection device that is a back-illuminated complementary metal oxide semiconductor (CMOS) image sensor will be described.

### (Overall Configuration of Solid-State Imaging Element)

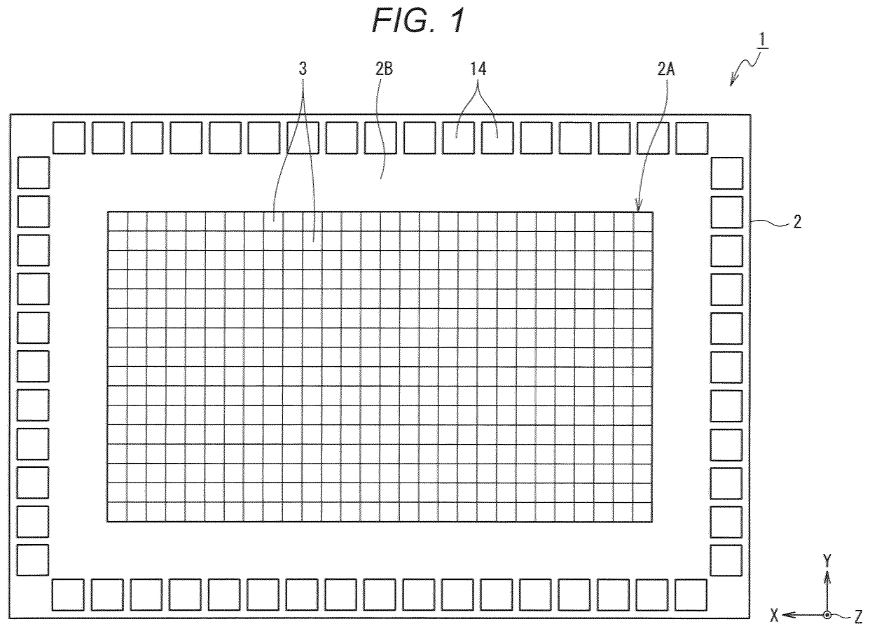

First, an overall configuration of a photodetection device 1 is described. As illustrated in FIG. 1, the photodetection device 1 according to the first embodiment of the present technology is formed mainly with a semiconductor chip 2 having a rectangular two-dimensional planar shape in a planar view. That is, the photodetection device 1 is mounted on the semiconductor chip 2. The photodetection device 1 captures image light from a subject via an optical lens (not illustrated), converts the amount of incident light formed on an imaging surface into an electrical signal in units of pixels, and outputs the electrical signal as a pixel signal.

As illustrated in FIG. 1, the semiconductor chip 2 on which the photodetection device 1 is mounted includes, in a two-dimensional plane including an X direction and a Y direction intersecting each other, a rectangular pixel region 2A provided in a central portion, and a peripheral region 2B provided outside the pixel region 2A to surround the pixel region 2A.

The pixel region 2A is, for example, a light receiving surface that receives light condensed by the optical lens. Further, in the pixel region 2A, a plurality of pixels 3 is arranged in a matrix in the two-dimensional plane including the X direction and the Y direction. In other words, the pixels 3 are repeatedly arranged in each of the X direction and the Y direction intersecting each other in the two-dimensional plane. Note that, in the present embodiment, the X direction and the Y direction are orthogonal to each other, for example. In addition, a direction orthogonal to both the X direction and the Y direction is a Z direction (thickness direction).

As illustrated in FIG. 1, a plurality of bonding pads 14 is arranged in the peripheral region 2B. Each bonding pad of the plurality of bonding pads 14 is arranged along each of the four sides of the two-dimensional plane of the semiconductor chip 2, for example. Each of the plurality of bonding pads 14 is an input/output terminal used when the semiconductor chip 2 is electrically connected to an external device.

### (Logic Circuit)

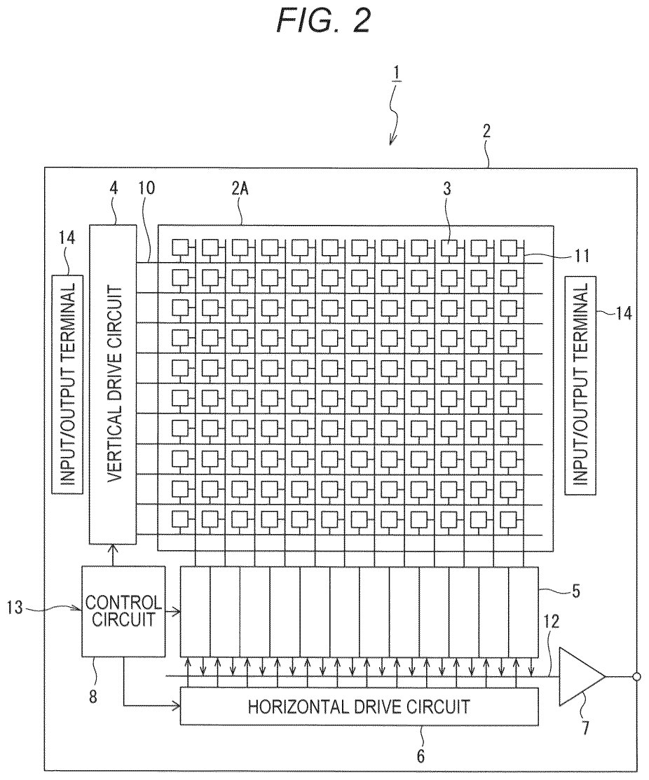

As illustrated in FIG. 2, the semiconductor chip 2 includes a logic circuit 13 including a vertical drive circuit 4, column signal processing circuits 5, a horizontal drive circuit 6, an output circuit 7, a control circuit 8, and the like. The logic circuit 13 includes, for example, a complementary MOS (CMOS) circuit including an n-channel conductive metal oxide semiconductor field effect transistor (MOSFET) and a p-channel conductive MOSFET as field effect transistors.

The vertical drive circuit 4 includes, for example, a shift register. The vertical drive circuit 4 sequentially selects a desired pixel drive line 10, supplies a pulse for driving the pixels 3 to the selected pixel drive line 10, and drives the respective pixels 3 row by row. That is, the vertical drive circuit 4 selectively scans each pixel 3 in the pixel region 2A sequentially in a vertical direction row by row, and supplies a pixel signal from the pixel 3 based on a signal charge generated in accordance with the amount of received light by a photoelectric conversion element of each pixel 3 to the column signal processing circuit 5 through a vertical signal line 11.

The column signal processing circuit 5 is arranged, for example, for every column of the pixels 3 and performs signal processing, such as noise removal on signals output from the pixels 3 of one row, for every pixel column. For example, each column signal processing circuit 5 performs signal processing such as correlated double sampling (CDS) for removing pixel-specific fixed pattern noise, and analog digital (AD) conversion. A horizontal selection switch (not illustrated) is provided at an output stage of the column signal processing circuit 5 to be connected with a horizontal signal line 12.

The horizontal drive circuit 6 includes, for example, a shift register. The horizontal drive circuit 6 sequentially outputs horizontal scanning pulses to the column signal processing circuits 5 to sequentially select each of the column signal processing circuits 5, and causes each of the column signal processing circuits 5 to output the pixel signal subjected to the signal processing to the horizontal signal line 12.

The output circuit 7 performs signal processing on pixel signals sequentially supplied from each of the column signal processing circuits 5 through the horizontal signal line 12, and outputs the signals. As the signal processing, for example, buffering, black level adjustment, column variation correction, various digital signal processing, and the like can be used.

The control circuit 8 generates, on the basis of a vertical synchronization signal, a horizontal synchronization signal, and a master clock signal, a clock signal or a control signal in accordance with which the vertical drive circuit 4, the column signal processing circuit 5, the horizontal drive circuit 6, and the like operate. Then, the control circuit 8 outputs the clock signal or control signal thus generated to the vertical drive circuit 4, the column signal processing circuit 5, the horizontal drive circuit 6, and the like.

### (Pixel)

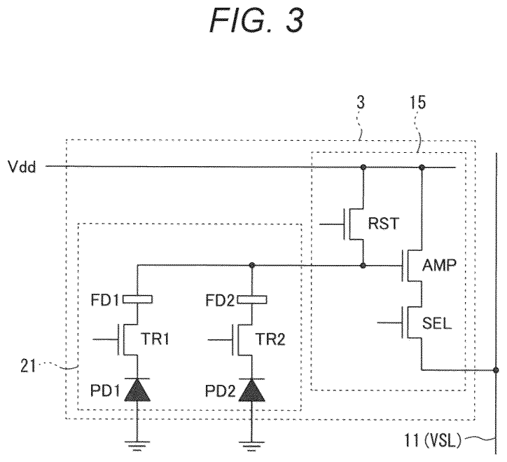

As illustrated in FIG. 3, each of the pixels 3 includes a photoelectric conversion unit 21. The photoelectric conversion unit 21 includes photoelectric conversion elements PD1 and PD2, charge accumulation regions (floating diffusion) FD1 and FD2 that accumulate (hold) signal charges photoelectrically converted by the photoelectric conversion elements PD1 and PD2, and transfer transistors TR1 and TR2 that transfer the signal charges photoelectrically converted by the photoelectric conversion elements PD1 and PD2 to the charge accumulation regions FD1 and FD2. Furthermore, each pixel 3 of the plurality of pixels 3 includes a readout circuit 15 electrically connected to the photoelectric conversion unit 21, more specifically, the charge accumulation regions FD1 and FD2.

Each of the two photoelectric conversion elements PD1 and PD2 generates a signal charge corresponding to the amount of received light. The photoelectric conversion elements PD1 and PD2 also temporarily accumulate (hold) the generated signal charges. The photoelectric conversion element PD1 has a cathode side electrically connected to a source region of the transfer transistor TR1, and an anode side electrically connected to a reference potential line (for example, ground). The photoelectric conversion element PD2 has a cathode side electrically connected to a source region of the transfer transistor TR2, and an anode side electrically connected to a reference potential line (for example, ground). As the photoelectric conversion elements PD1 and PD2, for example, photodiodes are used.

Among the two transfer transistors TR1 and TR2, the drain region of the transfer transistor TR1 is electrically connected to the charge accumulation region FD1. Agate electrode of the transfer transistor TR1 is electrically connected to a transfer transistor drive line among the pixel drive lines 10 (see FIG. 2). A drain region of the transfer transistor TR2 is electrically connected to the charge accumulation region FD2. A gate electrode of the transfer transistor TR2 is electrically connected to the transfer transistor drive line of the pixel drive line 10.

The charge accumulation region FD1 of the two charge accumulation regions FD1 and FD2 temporarily accumulates and holds the signal charge transferred from the photoelectric conversion element PD1 via the transfer transistor TR1. The charge accumulation region FD2 temporarily accumulates and holds the signal charges transferred from the photoelectric conversion element PD2 via the transfer transistor TR2.

The readout circuit 15 reads the signal charges accumulated in the charge accumulation regions FD1 and FD2, and outputs pixel signals based on the signal charges. Although not limited to this, the readout circuit 15 includes an amplification transistor AMP, a selection transistor SEL, and a reset transistor RST as pixel transistors, for example. These transistors (AMP, SEL, and RST) include, for example, a MOSFET having a gate insulating film constituted by a silicon oxide film (SiO2 film), a gate electrode, and a pair of main electrode regions functioning as a source region and a drain region. In addition, as these transistors, the gate insulating film may be a silicon nitride film (Si3N4 film) or a metal insulator semiconductor FET (MISFET) including a laminated film such as a silicon nitride film and a silicon oxide film.

The amplification transistor AMP has a source region electrically connected to a drain region of the selection transistor SEL, and a drain region electrically connected to a power supply line Vdd and a drain region of the reset transistor. Then, a gate electrode of the amplification transistor AMP is electrically connected to the charge accumulation regions FD1 and FD2 and a source region of the reset transistor RST.

The selection transistor SEL has a source region electrically connected to the vertical signal line 11 (VSL), and a drain electrically connected to the source region of the amplification transistor AMP. Then, a gate electrode of the selection transistor SEL is electrically connected to a selection transistor drive line among the pixel drive lines 10 (see FIG. 2).

The reset transistor RST has a source region electrically connected to the charge accumulation regions FD1 and FD2 and the gate electrode of the amplification transistor AMP, and a drain region electrically connected to the power supply line Vdd and the drain region of the amplification transistor AMP. Agate electrode of the reset transistor RST is electrically connected to a reset transistor drive line among the pixel drive lines 10 (see FIG. 2).

An electronic apparatus including the photodetection device 1 reads signal charges from each of the two photoelectric conversion elements PD1 and PD2 and detects a phase difference thereof. In the case of in-focus, there is no difference in the amount of signal charges accumulated in the photoelectric conversion element PD1 and the photoelectric conversion element PD2. On the other hand, in a case where focus is not achieved, there is a difference between the amount of signal charges accumulated in the photoelectric conversion element PD1 and the amount of signal charges accumulated in the photoelectric conversion element PD2. In a case where focus is not achieved, the electronic apparatus performs an operation such as operating the objective lens to match the amount of signal charges accumulated in the photoelectric conversion element PD1 with the amount of signal charges accumulated in the photoelectric conversion element PD2. This is autofocusing.

Then, when the focus adjustment is completed, the electronic apparatus generates an image by using the added signal charge of the signal charge accumulated in the photoelectric conversion element PD1 and the signal charge accumulated in the photoelectric conversion element PD2.

### (Laminated Structure of Photodetection Device)

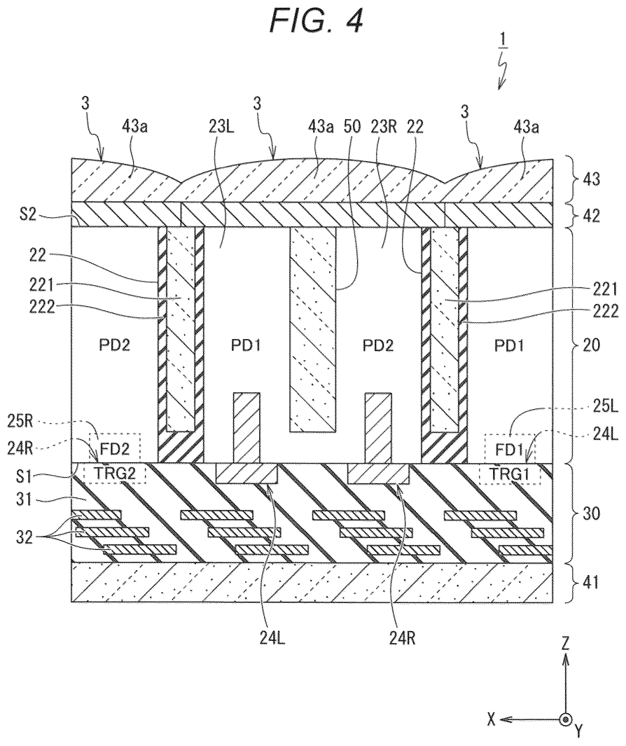

FIG. 4 is a partial longitudinal cross-sectional view illustrating an example of a laminated structure of the photodetection device 1 according to the first embodiment of the present disclosure. As illustrated in FIG. 4, the photodetection device 1 includes a semiconductor layer 20 having a first surface S1 and a second surface S2 located opposite to each other, a multilayer wiring layer 30 including an interlayer insulating film 31 and a wiring layer 32 sequentially provided on the first surface S1 side of the semiconductor layer 20 from the first surface S1 side, and a support substrate 41. In addition, the semiconductor chip 2 includes known members such as a color filter 42 and an on-chip lens layer 43 on the second surface S2 side of the semiconductor layer 20. Here, illustration of a known member other than the color filter 42 and the on-chip lens layer 43 is omitted. Furthermore, the on-chip lens layer 43 includes a plurality of on-chip lenses 43a.

The semiconductor layer 20 includes, for example, a single crystal silicon substrate. Then, a p-type well region is provided in the semiconductor layer 20. The semiconductor layer 20 is a functional layer in which the first photoelectric conversion section 23L and the second photoelectric conversion section 23R such as the photoelectric conversion elements PD1 and PD2 constituting each pixel 3 are formed. The first photoelectric conversion section 23L and the second photoelectric conversion section 23R of the semiconductor layer 20 generate a charge amount corresponding to the intensity of light incident via the on-chip lens 43a and the color filter 42.

Each of the color filter 42 and the on-chip lens 43a is provided for each pixel 3. The color filter 42 color-separates incident light incident from the light incident surface side of the semiconductor chip 2 and passing through the on-chip lens 43a. The on-chip lens 43a condenses the irradiation light and causes the condensed light to efficiently enter the pixel 3. Furthermore, one color filter 42 and one on-chip lens 43a are provided so as to cover both the first photoelectric conversion section 23L and the second photoelectric conversion section 23R.

Here, the first surface S1 of the semiconductor layer 20 may be referred to as an element formation surface or a front surface, and the second surface S2 side may be referred to as a light incident surface or a back surface. In the photodetection device 1 of the first embodiment, light incident from the second surface (light incident surface or back surface) S2 side of the semiconductor layer 20 is photoelectrically converted by the first photoelectric conversion section 23L and the second photoelectric conversion section 23R provided in the semiconductor layer 20. Each of the first photoelectric conversion section 23L and the second photoelectric conversion section 23R also functions as a charge accumulation region that temporarily accumulates the generated signal charge. The first photoelectric conversion section 23L and the second photoelectric conversion section 23R are arranged along the first direction in the pixel 3. Here, the first direction is described as the X direction, but may be a direction other than the X direction as long as it is a direction perpendicular to the thickness direction. In addition, each of the first photoelectric conversion section 23L and the second photoelectric conversion section 23R includes a second conductivity type, for example, an n-type semiconductor region.

The first photoelectric conversion section 23L, the second photoelectric conversion section 23R, and various electronic elements are electrically connected to predetermined wiring in the multilayer wiring layer 30. The multilayer wiring layer 30 is a layer in which wiring for transmitting power and various drive signals to each pixel 3 in the semiconductor layer 20 and transmitting a pixel signal read from each pixel 3 is formed.

Furthermore, in the semiconductor layer 20, an inter-pixel separation section 22 that separates the pixels 3 from each other can be formed.

The inter-pixel separation section 22 is formed by, for example, etching processing, and includes a full trench (FFTI) extending from the first surface S1 to the second surface S2. The inter-pixel separation section 22 prevents light incident on the pixel 3 from entering the adjacent pixel 3. Furthermore, the inter-pixel separation section 22 includes the semiconductor region 221 or the dielectric into which the impurity having the first conductivity type is implanted, and the interface layer 222 covering the semiconductor region 221 or the periphery of the dielectric, and functions as a separation region that suppresses the movement of the signal charge between the two adjacent pixels 3. Note that, as the impurity exhibiting the first conductivity type, for example, an impurity exhibiting p-type is used. Furthermore, a metal oxide film or silicon oxide (SiO2) is used for the interface layer 222.

In the semiconductor layer 20, an intra-pixel separation section 50 is formed between the first photoelectric conversion section 23L and the second photoelectric conversion section 23R. The intra-pixel separation section 50 separates the first photoelectric conversion section 23L and the second photoelectric conversion section 23R. Furthermore, the intra-pixel separation section 50 includes a semiconductor region into which an impurity having the first conductivity type is implanted, and includes a back surface trench (RDTI) extending in the thickness direction of the semiconductor layer 20 from the second surface S2 side.

Furthermore, the semiconductor layer 20 is provided with a first charge accumulation region 25L and a second charge accumulation region 25R. The first charge accumulation region 25L is a charge accumulation region that is provided closer to the first surface S1 side of the semiconductor layer 20 and temporarily accumulates the signal charge transferred from the first photoelectric conversion section 23L. The first charge accumulation region 25L is a floating diffusion region of the second conductivity type, for example, n-type. The second charge accumulation region 25R is a charge accumulation region that is provided closer to the first surface S1 side of the semiconductor layer 20 and temporarily accumulates the signal charge transferred from the second photoelectric conversion section 23R. The second charge accumulation region 25R is a floating diffusion region of the second conductivity type, for example, n-type.

### (Transfer Transistor)

The first transfer transistor 24L illustrated in FIG. 4 corresponds to the transfer transistor TR1 of FIG. 3. The first transfer transistor 24L is provided on the first surface S1 side of the semiconductor layer 20 and is, for example, an n-channel MOSFET. The first transfer transistor 24L is provided so as to form a channel in an active region between the first photoelectric conversion section 23L and the first charge accumulation region 25L, and includes a gate insulating film (not illustrated) and a transfer gate electrode TRG1 sequentially laminated on the first surface S1. The first transfer transistor 24L may or may not transfer the signal charge from the first photoelectric conversion section 23L functioning as the source region to the first charge accumulation region 25L functioning as the drain region by being turned on and off according to the voltage between the gate and the source. Here, it is assumed that the signal charge is transferred when the first transfer transistor 24L is on, and the signal charge is not transferred when the first transfer transistor 24L is off.

The second transfer transistor 24R illustrated in FIG. 4 corresponds to the transfer transistor TR2 in FIG. 3. The second transfer transistor 24R is provided on the first surface S1 side of the semiconductor layer 20 and is, for example, an n-channel MOSFET. The second transfer transistor 24R is provided so as to form a channel in an active region between the second photoelectric conversion section 23R and the second charge accumulation region 25R, and includes a gate insulating film (not illustrated) and a transfer gate electrode TRG2 sequentially laminated on the first surface S1. The second transfer transistor 24R may or may not transfer the signal charge from the second photoelectric conversion section 23R functioning as the source region to the second charge accumulation region 25R functioning as the drain region by being turned on and off according to the voltage between the gate and the source. Here, it is assumed that the signal charge is transferred when the second transfer transistor 24R is turned on, and the signal charge is not transferred when the second transfer transistor 24R is turned off.

### (Reset Transistor)

The reset transistor RST is, for example, an n-channel MOSFET. The reset transistor RST includes a gate insulating film and a reset gate electrode (not illustrated) sequentially laminated on the first surface S1. The reset transistor RST is turned on and off according to the voltage between the gate and the source. Then, when the reset transistor RST is turned on, the potentials of the first charge accumulation region 25L (FD1) and the second charge accumulation region 25R (FD2) are reset to a predetermined potential.

### (Selection Transistor)

The selection transistor SEL is, for example, an n-channel MOSFET. The selection transistor SEL includes a gate insulating film and a selection gate electrode (not illustrated) sequentially laminated on the first surface S1. The selection transistor SEL is turned on and off according to the voltage between the gate and the source. Then, the pixel signal is output from the readout circuit 15 at the timing when the selection transistor SEL is turned on.

### (Amplification Transistor)

The amplification transistor AMP is, for example, an n-channel MOSFET. The amplification transistor AMP includes a gate insulating film and an amplification gate electrode (not illustrated) sequentially laminated on the first surface S1. When the selection transistor SEL is turned on, the amplification transistor AMP amplifies the potential of the first charge accumulation region 25L and/or the second charge accumulation region 25R.

### Comparative Example of Embodiment

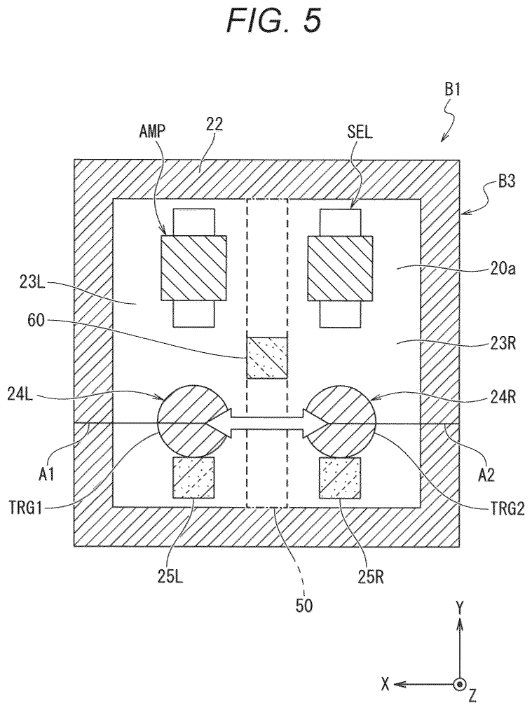

FIG. 5 is a transverse cross-sectional view illustrating a relative relationship between respective configurations when the pixel B3 in the comparative example is viewed in cross section on the first surface S1. In FIG. 5, the same portions as those in above FIGS. 3 and 4 are denoted by the same reference signs, and a detailed description thereof is omitted.

In the photodetection device B1, each of the pixels B3 includes a first photoelectric conversion section 23L (photoelectric conversion element PD1), a second photoelectric conversion section 23R (photoelectric conversion element PD2), a vertical gate electrode TRG1 of the first transfer transistor 24L, a vertical gate electrode TRG2 of the second transfer transistor 24R, a first charge accumulation region (FD1) 25L, a second charge accumulation region (FD2) 25R, an amplification transistor AMP as a pixel transistor, a selection transistor, and a contact 60 of a p-type well region, which are provided in the active region 20a. For example, a predetermined potential for driving the first photoelectric conversion section 23L (photoelectric conversion element PD1), the second photoelectric conversion section 23R (photoelectric conversion element PD2), the first transfer transistor 24L, the second transfer transistor 24R, the amplification transistor AMP, and the selection transistor is applied to the contact 60 of the p-type well region.

The inter-pixel separation section 22 is formed on the outer edge of the pixel B3. The inter-pixel separation section 22 is formed in a lattice shape so as to surround each pixel B3.

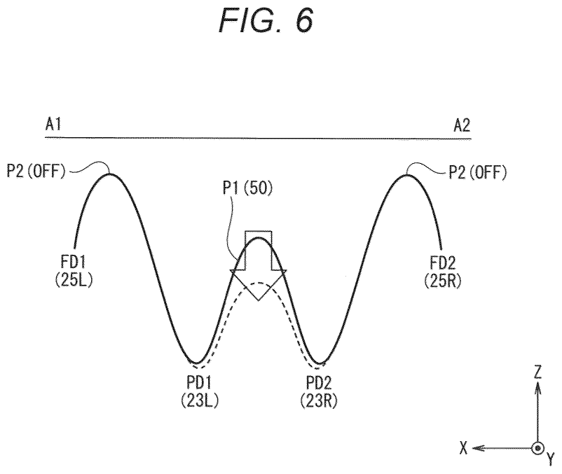

FIG. 6 is a schematic diagram illustrating a relationship between potential distributions of components in A1-A2 in FIG. 5. When light enters the photodetection device B1, the light passes through the on-chip lens 43a, the color filter 42, and the like and enters the first photoelectric conversion section 23L and the second photoelectric conversion section 23R. Then, an output Q1 is obtained from the first photoelectric conversion section 23L and an output Q2 is obtained from the second photoelectric conversion section 23R according to the amount of incident light. Then, autofocus is performed on the basis of the outputs Q1 and Q2, and an image is generated on the basis of the LR addition signal Q3 (Q3=Q1+Q2) which is the sum of Q1 and Q2.

For example, when the pixel B3 is miniaturized, the first transfer transistor 24L and the second transfer transistor 24R come close to the intra-pixel separation section 50 on the element formation surface, that is, the distance between the first transfer transistor 24L and the second transfer transistor 24R and the intra-pixel separation section 50 decreases. Then, there is a possibility that the height of the first potential barrier P1 of the intra-pixel separation section 50 changes due to the influence of modulation when the first transfer transistor 24L and the second transfer transistor 24R are turned on and off.

When the first transfer transistor 24L is turned on, the second potential barrier P2 corresponding to the first transfer transistor 24L is lowered, and the signal charge accumulated in the first photoelectric conversion section 23L flows to the first charge accumulation region 25L. The first potential barrier P1 of the intra-pixel separation section 50 is also affected by the modulation of the first transfer transistor 24L, and the height of the barrier decreases as indicated by an arrow in FIG. 6. Since the first potential barrier P1 becomes low, a part of the signal charges accumulated in the second photoelectric conversion section 23R flows to the first charge accumulation region 25L beyond the first potential barrier P1. Then, the first transfer transistor 24L is turned off, and the first potential barrier P1 and the second potential barrier P2 return to the original heights. However, since a part of the signal charges accumulated in the second photoelectric conversion section 23R has flown out, the amount thereof is reduced.

For this reason, there is a risk that the saturation signal amount of one photodiode decreases, and there is a risk that the left-right potential, that is, the first potential barrier P1 becomes too deep at the time of LR (left-right) addition reading, and the electronic readout deteriorates.

### Solving Means of First Embodiment

Therefore, in the first embodiment of the present disclosure, the layout is changed so that the vertical gate electrode TRG1 of the first transfer transistor 24L and the vertical gate electrode TRG2 of the second transfer transistor 24R are not adjacent to each other.

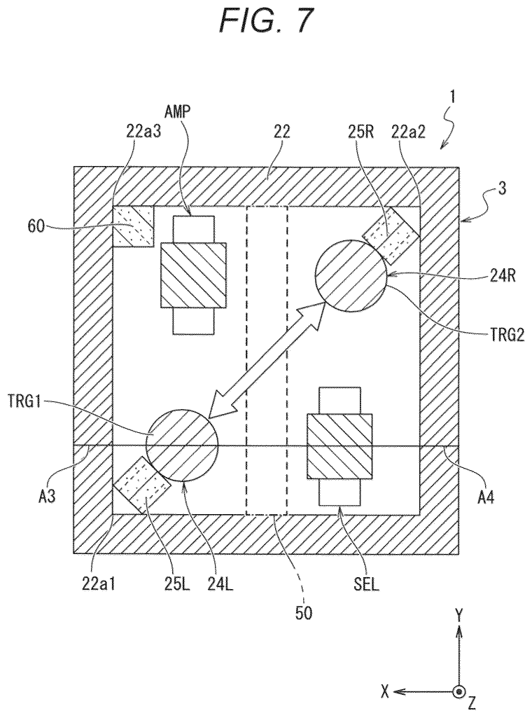

FIG. 7 is a transverse cross-sectional view illustrating a relative relationship between respective configurations when the pixel 3 in the first embodiment of the present disclosure is viewed in cross section along a first surface S1. In FIG. 7, the same portions as those in above FIG. 5 are denoted by the same reference signs, and a detailed description thereof is omitted.

In the pixel 3, the vertical gate electrode TRG1 of the first transfer transistor 24L and the vertical gate electrode TRG2 of the second transfer transistor 24R are arranged along a diagonal line connecting the pixel 3, that is, the two corner portions 22a1 and 22a2 of the inter-pixel separation section 22 with the intra-pixel separation section 50 interposed therebetween in plan view, and the distance between the vertical gate electrodes TRG1 and TRG2 is increased, so that the left-right potential, that is, the first potential barrier P1 of the intra-pixel separation section 50 can be made less likely to be modulated. The contact 60 of the p-type well region is arranged at the corner portion 22a3 of the inter-pixel separation section 22.

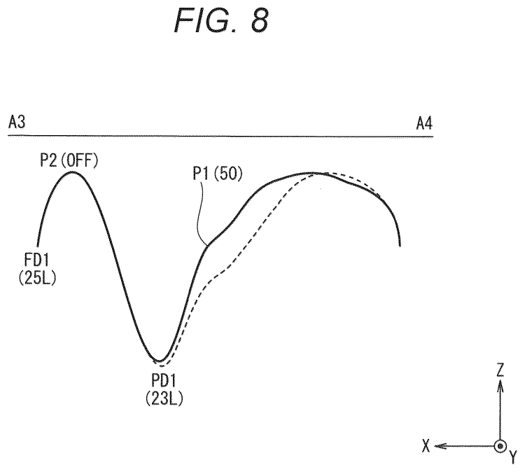

FIG. 8 is a schematic diagram illustrating a relationship between potential distributions of components in A3-A4 in FIG. 7.

When the first transfer transistor 24L is turned on, the second potential barrier P2 corresponding to the first transfer transistor 24L is lowered, and the signal charge accumulated in the first photoelectric conversion section 23L flows to the first charge accumulation region 25L. The first potential barrier P1 of the intra-pixel separation section 50 is also affected by the modulation of the first transfer transistor 24L, and the height of the barrier decreases as indicated by a dotted line in FIG. 8. However, since the vertical gate electrode TRG1 of the first transfer transistor 24L and the vertical gate electrode TRG2 of the second transfer transistor 24R are separated from each other, a blooming path (BLM path) is not formed between the first photoelectric conversion section 23L and the second photoelectric conversion section 23R, and a part of signal charges accumulated in the second photoelectric conversion section 23R can be prevented from flowing to the first charge accumulation region 25L beyond the first potential barrier P1.

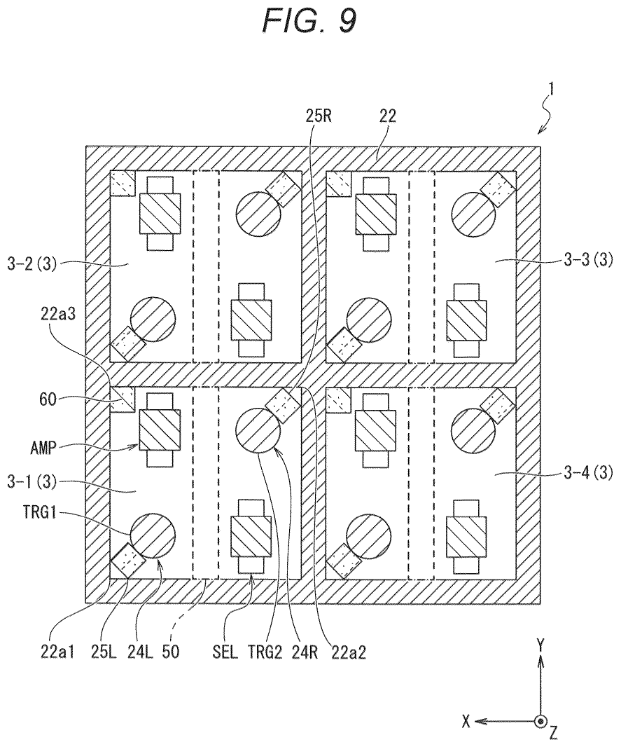

FIG. 9 is a plan view illustrating an arrangement relationship of a plurality of pixels 3 of a photodetection device 1 according to the first embodiment of the present disclosure. In FIG. 9, the inter-pixel separation section 22 is formed in a lattice shape so as to surround each pixel (3-1, 3-2, 3-3, 3-4) 3. The pixels 3-1, 3-2, 3-3, and 3-4 have the same arrangement structure. The outer edge shape of each pixel 3 has a geometric shape having four or more sides or a geometric shape including a closed curve. The outer edge shape of the pixel 3 is defined by the inter-pixel separation section 22.

In the pixel 3-1, the vertical gate electrode TRG1 of the first transfer transistor 24L and the vertical gate electrode TRG2 of the second transfer transistor 24R are arranged along a diagonal line connecting two corner portions 22a1 and 22a2 of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2. The arrangement structure of the pixels 3-2, 3-3, and 3-4 is similar to that of the pixel 3-1.

A part of light (for example, near-infrared light or the like) incident on the second surface S2 of the semiconductor layer 20 can pass through the second surface S1. In the photodetection device 1 according to the first embodiment, since the first transfer transistor 24L contributing to reflection, the second transfer transistor 24R, the amplification transistor AMP as a pixel transistor, and the selection transistor are arranged at the same position with respect to the four pixels 3-1, 3-2, 3-3, and 3-4, the reflection intensity is the same in each of the pixels 3-1, 3-2, 3-3, and 3-4, and the pixel outputs are also the same.

### Functions and Effects of First Embodiment

As described above, according to the first embodiment, in the pixel 3, the vertical gate electrode TRG1 of the first transfer transistor 24L and the vertical gate electrode TRG2 of the second transfer transistor 24R are arranged along a diagonal line connecting two corner portions 22a1 and 22a2 of the inter-pixel separation section 22 with the intra-pixel separation section 50 interposed therebetween in plan view, and the distance between the vertical gate electrodes is widened, so that the left-right potential, that is, the first potential barrier P1 can be made difficult to be modulated. As a result, when one transfer transistor 24L is turned on, the left-right potential is not modulated, the saturation signal amount of the first photoelectric conversion section 23L and the saturation signal amount of the second photoelectric conversion section 23R are maintained, and deterioration of electronic readout can be avoided.

Furthermore, according to the first embodiment, since the respective pixels 3-1, 3-2, 3-3, and 3-4 have the same arrangement structure, for example, even when near-infrared light is incident, it is possible to reduce an output difference between the respective pixels 3-1, 3-2, 3-3, and 3-4.

### First Modification of First Embodiment

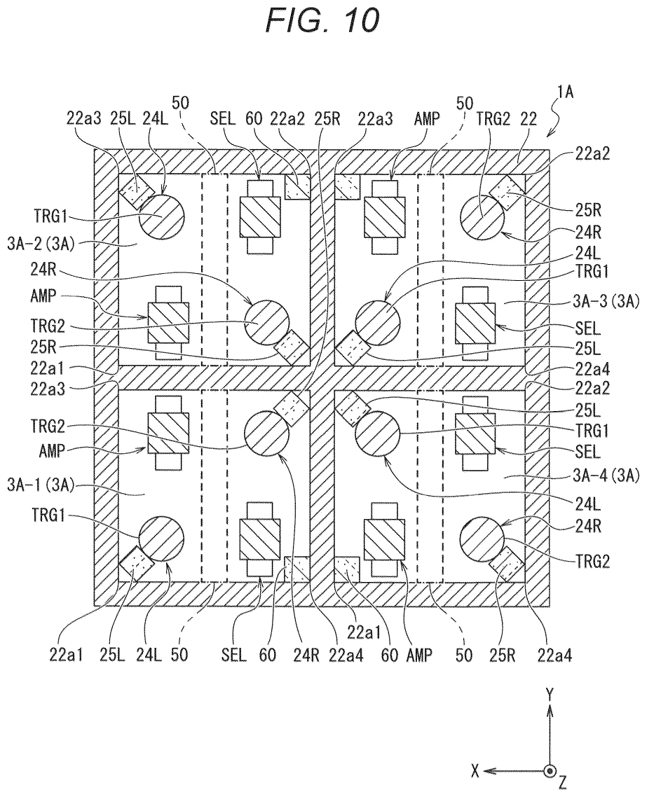

FIG. 10 is a plan view illustrating an arrangement relationship of a plurality of pixels 3A of a photodetection device 1A according to the first modification of the first embodiment of the present disclosure. In FIG. 10, the same portions as those in above FIG. 9 are denoted by the same reference signs, and a detailed description thereof is omitted.

In the pixel 3A-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 10) and 22a2 (upper right corner portion in FIG. 10) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 10) of the inter-pixel separation section 22. Furthermore, the selection transistor SEL is arranged on the side of the corner portion 22a4 (the lower right corner portion in FIG. 10) of the inter-pixel separation section 22. A contact 60 of a p-type well region is arranged between the selection transistor SEL and the corner portion 22a4 of the inter-pixel separation section 22.

In the pixel 3A-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 10) and 22a4 (lower right corner portion in FIG. 10) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 10) of the inter-pixel separation section 22. Furthermore, the selection transistor SEL is arranged on the side of the corner portion 22a2 (the upper right corner portion in FIG. 10) of the inter-pixel separation section 22. A contact 60 of a p-type well region is arranged between the selection transistor SEL and the corner portion 22a2 of the inter-pixel separation section 22.

In the pixel 3A-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 10) and 22a2 (upper right corner portion in FIG. 10) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 10) of the inter-pixel separation section 22. Furthermore, the selection transistor SEL is arranged on the side of the corner portion 22a4 (the lower right corner portion in FIG. 10) of the inter-pixel separation section 22. A contact 60 of a p-type well region is arranged between the amplification transistor AMP and the corner portion 22a3 of the inter-pixel separation section 22.

In the pixel 3A-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 10) and 22a4 (lower right corner portion in FIG. 10) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 10) of the inter-pixel separation section 22. Furthermore, the selection transistor SEL is arranged on the side of the corner portion 22a2 (the upper right corner portion in FIG. 10) of the inter-pixel separation section 22. A contact 60 of a p-type well region is arranged between the amplification transistor AMP and the corner portion 22a1 of the inter-pixel separation section 22.

In the first modification of the first embodiment of the present disclosure, the first charge accumulation region 25L and the second charge accumulation region 25R can be collectively arranged and shared in one place between the four adjacent pixels 3A-1, 3A-2, 3A-3, and 3A-4, and further, the contacts 60 of the p-type well region can be collectively arranged in one place between the two adjacent pixels 3A-1 and 3A-4, and the contacts 60 of the p-type well region can be collectively arranged and shared in one place between the two adjacent pixels 3A-2 and 3A-3.

Note that, in the first modification, in a case where the first charge accumulation region 25L and the second charge accumulation region 25R are shared among the four pixels 3A-1, 3A-2, 3A-3, and 3A-4, at least one amplification transistor AMP and at least one selection transistor SEL are only required to be provided. In addition, a reset transistor RST may be arranged other than the amplification transistor AMP and the selection transistor SEL, and a conversion efficiency switching transistor FDG may be arranged other than the reset transistor RST.

### Functions and Effects of First Modification of First Embodiment

As described above, according to the first modification of the first embodiment, the first charge accumulation region 25L and the second charge accumulation region 25R can be collectively arranged in one place between the four adjacent pixels 3A-1, 3A-2, 3A-3, and 3A-4, and further, the contacts 60 of the p-type well region can be collectively arranged in one place between the two adjacent pixels 3A-1 and 3A-4, and the contacts 60 of the p-type well region can be collectively arranged in one place between the two adjacent pixels 3A-2 and 3A-3, so that the layout efficiency is improved.

### Second Modification of First Embodiment

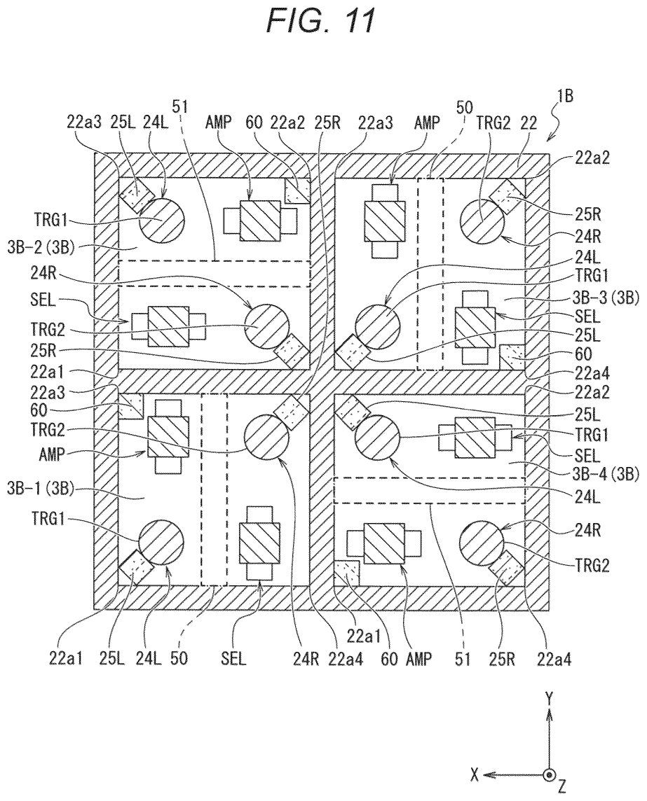

FIG. 11 is a plan view illustrating an arrangement relationship of a plurality of pixels 3B of a photodetection device 1B according to the second modification of the first embodiment of the present disclosure. In FIG. 11, the same portions as those in above FIG. 9 are denoted by the same reference signs, and a detailed description thereof is omitted.

In the second modification, the intra-pixel separation section 50 of the pixel 3B-1 extends in the direction indicated by the arrow Y in FIG. 11, and the intra-pixel separation section 51 of the pixel 3B-2 extends in the direction indicated by the arrow X in FIG. 11 rotated by 90° with respect to the intra-pixel separation section 50. Similarly, the intra-pixel separation section 50 of the pixel 3B-3 extends in the direction indicated by the arrow Y in FIG. 11, and the intra-pixel separation section 51 of the pixel 3B-4 extends in the direction indicated by the arrow X in FIG. 11 rotated by 90° with respect to the intra-pixel separation section 50.

In the pixel 3B-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 11) and 22a2 (upper right corner portion in FIG. 11) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 11) of the inter-pixel separation section 22. Furthermore, the selection transistor SEL is arranged on the side of the corner portion 22a4 (the lower right corner portion in FIG. 11) of the inter-pixel separation section 22. A contact 60 of a p-type well region is arranged between the amplification transistor AMP and the corner portion 22a3 of the inter-pixel separation section 22.

In the pixel 3B-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 11) and 22a4 (lower right corner portion in FIG. 11) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The selection transistor SEL is arranged on the side of the corner portion 22a1 (the lower left corner portion in FIG. 11) of the inter-pixel separation section 22. Furthermore, the amplification transistor AMP is arranged on the side of the corner portion 22a2 (the upper right corner portion in FIG. 11) of the inter-pixel separation section 22. A contact 60 of a p-type well region is arranged between the amplification transistor AMP and the corner portion 22a2 of the inter-pixel separation section 22.

In the pixel 3B-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 11) and 22a2 (upper right corner portion in FIG. 11) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 11) of the inter-pixel separation section 22. Furthermore, the selection transistor SEL is arranged on the side of the corner portion 22a4 (the lower right corner portion in FIG. 11) of the inter-pixel separation section 22. A contact 60 of a p-type well region is arranged between the selection transistor SEL and the corner portion 22a4 of the inter-pixel separation section 22.

In the pixel 3B-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 11) and 22a4 (lower right corner portion in FIG. 11) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 11) of the inter-pixel separation section 22. Furthermore, the selection transistor SEL is arranged on the side of the corner portion 22a2 (the upper right corner portion in FIG. 11) of the inter-pixel separation section 22. A contact 60 of a p-type well region is arranged between the amplification transistor AMP and the corner portion 22a1 of the inter-pixel separation section 22.

### Functions and Effects of Second Modification of First Embodiment

As described above, according to the second modification of the first embodiment, it is possible to obtain phase difference detection information in both the direction indicated by the arrow X in FIG. 11 and the direction indicated by the arrow Y in FIG. 11 for the same color from the output of each of the four pixels 3B-1, 3B-2, 3B-3, and 3B-4. This makes it possible to realize high performance image plane phase difference autofocus.

### Third Modification of First Embodiment

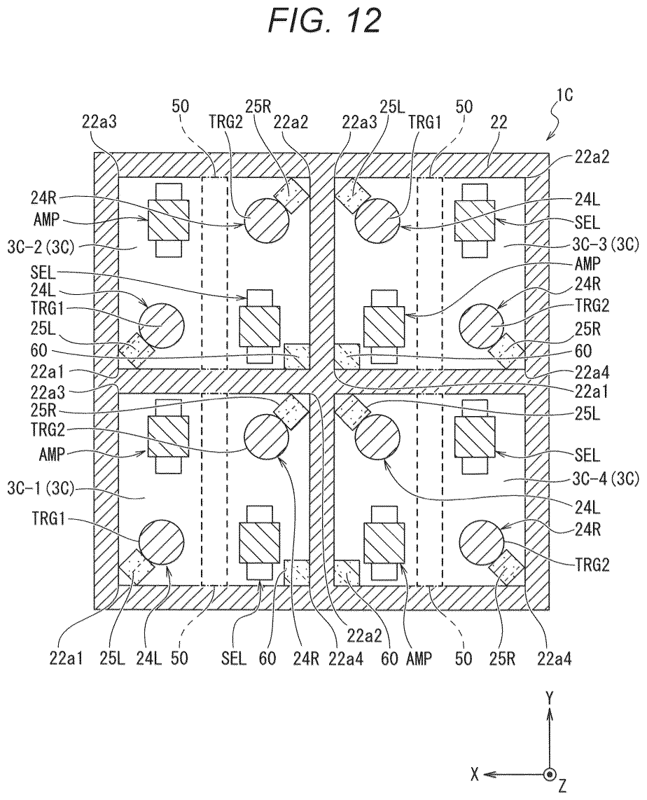

FIG. 12 is a plan view illustrating an arrangement relationship of a plurality of pixels 3C of a photodetection device 1C according to the third modification of the first embodiment of the present disclosure. In FIG. 12, the same portions as those in above FIG. 9 are denoted by the same reference signs, and a detailed description thereof is omitted.

In the pixel 3C-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 12) and 22a2 (upper right corner portion in FIG. 12) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 12) of the inter-pixel separation section 22. Furthermore, the selection transistor SEL is arranged on the side of the corner portion 22a4 (the lower right corner portion in FIG. 12) of the inter-pixel separation section 22. A contact 60 of a p-type well region is arranged between the selection transistor SEL and the corner portion 22a4 of the inter-pixel separation section 22. Note that the pixel 3C-2 has the same arrangement configuration as the pixel 3C-1.

In the pixel 3C-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 12) and 22a4 (lower right corner portion in FIG. 12) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 12) of the inter-pixel separation section 22. Furthermore, the selection transistor SEL is arranged on the side of the corner portion 22a2 (the lower right corner portion in FIG. 12) of the inter-pixel separation section 22. A contact 60 of a p-type well region is arranged between the amplification transistor AMP and the corner portion 22a1 of the inter-pixel separation section 22. Note that the pixel 3C-4 has the same arrangement configuration as the pixel 3C-3.

In the third modification of the first embodiment of the present disclosure, the first charge accumulation region 25L and the second charge accumulation region 25R can be collectively arranged and shared in one place between the two adjacent pixels 3C-1 and 3C-4, and further, the contact 60 of the p-type well region can be collectively arranged and shared in one place between the two adjacent pixels 3C-1 and 3C-4.

In addition, the first charge accumulation region 25L and the second charge accumulation region 25R can be collectively arranged and shared in one place between the two adjacent pixels 3C-2 and 3C-3, and the contact 60 of the p-type well region can be collectively arranged and shared in one place between the two adjacent pixels 3C-2 and 3C-3.

### Functions and Effects of Third Modification of First Embodiment

As described above, according to the third modification of the first embodiment, functions and effects similar to those of the above-described first embodiment and the first modification of the first embodiment can be obtained.

### Fourth Modification of First Embodiment

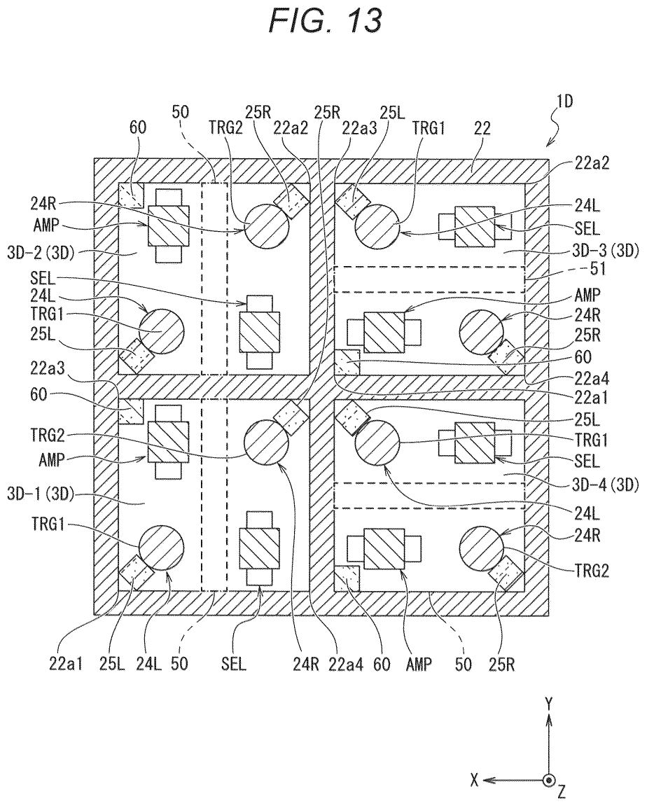

FIG. 13 is a plan view illustrating an arrangement relationship of a plurality of pixels 3D of a photodetection device 1D according to the fourth modification of the first embodiment of the present disclosure. In FIG. 13, the same portions as those in above FIG. 11 are denoted by the same reference signs, and a detailed description thereof is omitted.

In the pixel 3D-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 13) and 22a2 (upper right corner portion in FIG. 13) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 13) of the inter-pixel separation section 22. Furthermore, the selection transistor SEL is arranged on the side of the corner portion 22a4 (the lower right corner portion in FIG. 13) of the inter-pixel separation section 22. A contact 60 of a p-type well region is arranged between the selection transistor SEL and the corner portion 22a4 of the inter-pixel separation section 22. Note that the pixel 3D-2 has the same arrangement configuration as the pixel 3D-1.

In the pixel 3D-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 13) and 22a4 (lower right corner portion in FIG. 13) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 13) of the inter-pixel separation section 22. Furthermore, the selection transistor SEL is arranged on the side of the corner portion 22a2 (the lower right corner portion in FIG. 13) of the inter-pixel separation section 22. A contact 60 of a p-type well region is arranged between the amplification transistor AMP and the corner portion 22a1 of the inter-pixel separation section 22. Note that the pixel 3D-4 has the same arrangement configuration as the pixel 3D-3.

In the fourth modification of the first embodiment of the present disclosure, the first charge accumulation region 25L and the second charge accumulation region 25R can be collectively arranged and shared in one place between the two adjacent pixels 3D-1 and 3D-4.

Furthermore, the first charge accumulation region 25L and the second charge accumulation region 25R can be collectively arranged and shared in one place between the two adjacent pixels 3D-2 and 3D-3.

### Functions and Effects of Fourth Modification of First Embodiment

As described above, according to the fourth modification of the first embodiment, functions and effects similar to those of the above-described first embodiment and the second modification of the first embodiment can be obtained.

### Second Embodiment

In the second embodiment of the present disclosure, the contact 60 of the p-type well region is arranged at an equal distance from the first transfer transistor 24L, the second transfer transistor 24R, the amplification transistor AMP, and the selection transistor SEL in the pixel 3E.

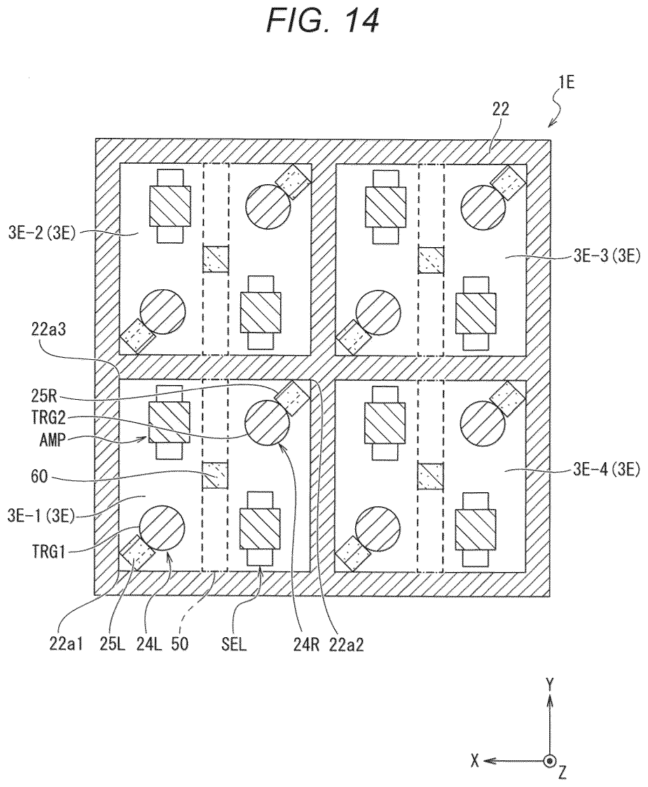

FIG. 14 is a plan view illustrating an arrangement relationship of a plurality of pixels 3E of a photodetection device 1E according to the second embodiment of the present disclosure. In FIG. 14, the same portions as those in above FIG. 9 are denoted by the same reference signs, and a detailed description thereof is omitted.

In the pixel 3E-1, the vertical gate electrode TRG1 of the first transfer transistor 24L and the vertical gate electrode TRG2 of the second transfer transistor 24R are arranged along a diagonal line connecting two corner portions 22a1 and 22a2 of the inter-pixel separation section 22 with the intra-pixel separation section 50 interposed therebetween. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 14) of the inter-pixel separation section 22. Furthermore, the selection transistor SEL is arranged on the side of the corner portion 22a4 (the lower right corner portion in FIG. 14) of the inter-pixel separation section 22. The contact 60 of the p-type well region is arranged at the center of the pixel 3E-1 on the first surface S1 side of the intra-pixel separation section 50. Note that the arrangement structure of the pixels 3-2, 3-3, and 3-4 is similar to that of the pixel 3-1.

### Functions and Effects of Second Embodiment

As described above, according to the second embodiment, functions and effects similar to those of the above-described first embodiment can be obtained, and the contact 60 of the p-type well region is arranged at the center of the pixel 3E, whereby a substantially stable potential can be applied to the first transfer transistor 24L, the second transfer transistor 24R, the amplification transistor AMP, and the selection transistor SEL.

### First Modification of Second Embodiment

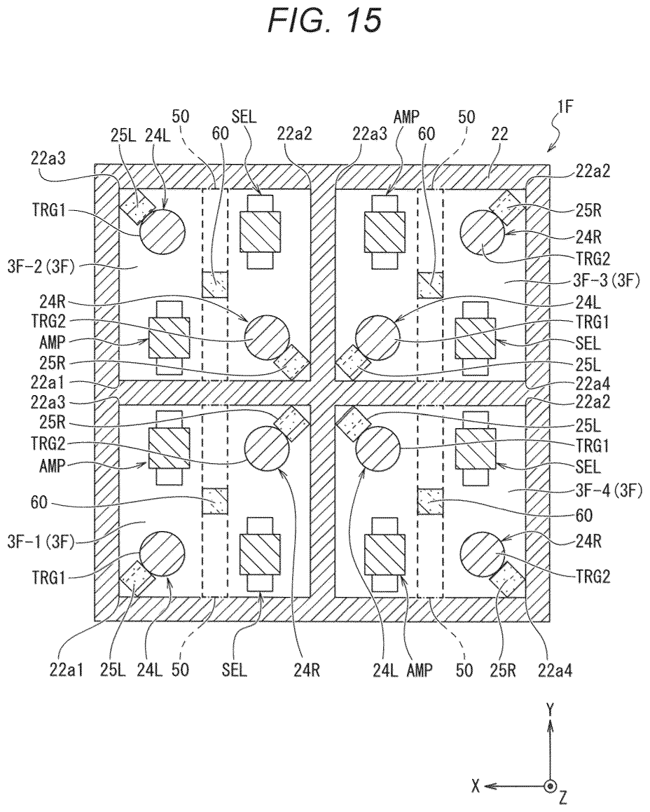

FIG. 15 is a plan view illustrating an arrangement relationship of a plurality of pixels 3F of a photodetection device 1F according to the first modification of the second embodiment of the present disclosure. In FIG. 15, the same portions as those in above FIG. 14 are denoted by the same reference signs, and a detailed description thereof is omitted.

In the pixel 3F-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 15) and 22a2 (upper right corner portion in FIG. 15) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 15) of the inter-pixel separation section 22. Furthermore, the selection transistor SEL is arranged on the side of the corner portion 22a4 (the lower right corner portion in FIG. 15) of the inter-pixel separation section 22. A contact 60 of a p-type well region is arranged at the center of the pixel 3F-1.

In the pixel 3F-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 15) and 22a4 (lower right corner portion in FIG. 15) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 15) of the inter-pixel separation section 22. Furthermore, the selection transistor SEL is arranged on the side of the corner portion 22a2 (the upper right corner portion in FIG. 15) of the inter-pixel separation section 22. A contact 60 of a p-type well region is arranged at the center of the pixel 3F-2.

In the pixel 3F-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 15) and 22a2 (upper right corner portion in FIG. 15) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 15) of the inter-pixel separation section 22. Furthermore, the selection transistor SEL is arranged on the side of the corner portion 22a4 (the lower right corner portion in FIG. 15) of the inter-pixel separation section 22. A contact 60 of a p-type well region is arranged at the center of the pixel 3F-3.

In the pixel 3F-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 15) and 22a4 (lower right corner portion in FIG. 15) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 15) of the inter-pixel separation section 22. Furthermore, the selection transistor SEL is arranged on the side of the corner portion 22a2 (the upper right corner portion in FIG. 15) of the inter-pixel separation section 22. A contact 60 of a p-type well region is arranged at the center of the pixel 3F-4.

In the first modification of the second embodiment of the present disclosure, the first charge accumulation region 25L and the second charge accumulation region 25R can be collectively arranged and shared in one place between the four adjacent pixels 3F-1, 3F-2, 3F-3, and 3F-4.

Note that, in the second modification, in a case where the first charge accumulation region 25L and the second charge accumulation region 25R are shared among the four pixels 3F-1, 3F-2, 3F-3, and 3F-4, at least one amplification transistor AMP and at least one selection transistor SEL are only required to be provided. In addition, a reset transistor RST may be arranged other than the amplification transistor AMP and the selection transistor SEL, and a conversion efficiency switching transistor FDG may be arranged other than the reset transistor RST.

### Functions and Effects of First Modification of Second Embodiment

As described above, according to the first modification of the second embodiment, functions and effects similar to those of the above-described second embodiment can be obtained, and the first charge accumulation region 25L and the second charge accumulation region 25R can be collectively arranged in one place between the four adjacent pixels 3F-1, 3F-2, 3F-3, and 3F-4, so that the layout efficiency is improved.

### Second Modification of Second Embodiment

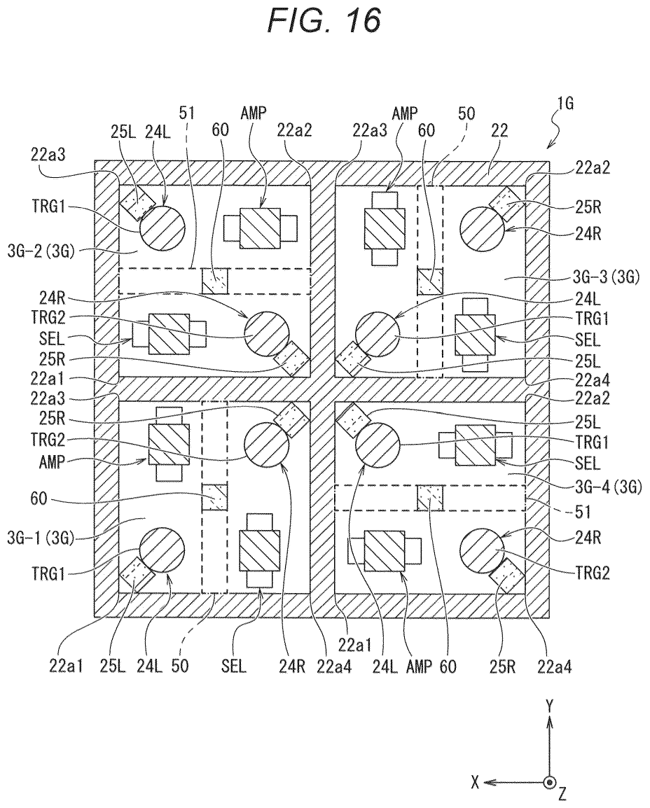

FIG. 16 is a plan view illustrating an arrangement relationship of a plurality of pixels 3G of a photodetection device 1G according to the second modification of the second embodiment of the present disclosure. In FIG. 16, the same portions as those in above FIG. 14 are denoted by the same reference signs, and a detailed description thereof is omitted.

In the second modification, the intra-pixel separation section 50 of the pixel 3G-1 extends in the direction indicated by the arrow Y in FIG. 16, and the intra-pixel separation section 51 of the pixel 3G-2 extends in the direction indicated by the arrow X in FIG. 16 rotated by 90° with respect to the intra-pixel separation section 50. Similarly, the intra-pixel separation section 50 of the pixel 3G-3 extends in the direction indicated by the arrow Y in FIG. 16, and the intra-pixel separation section 51 of the pixel 3G-4 extends in the direction indicated by the arrow X in FIG. 16 rotated by 90° with respect to the intra-pixel separation section 50.

In the pixel 3G-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 16) and 22a2 (upper right corner portion in FIG. 16) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 16) of the inter-pixel separation section 22. Furthermore, the selection transistor SEL is arranged on the side of the corner portion 22a4 (the lower right corner portion in FIG. 16) of the inter-pixel separation section 22. A contact 60 of a p-type well region is arranged at the center of the pixel 3G-1.

In the pixel 3G-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 16) and 22a4 (lower right corner portion in FIG. 16) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The selection transistor SEL is arranged on the side of the corner portion 22a1 (the lower left corner portion in FIG. 16) of the inter-pixel separation section 22. Furthermore, the amplification transistor AMP is arranged on the side of the corner portion 22a2 (the upper right corner portion in FIG. 16) of the inter-pixel separation section 22. A contact 60 of a p-type well region is arranged at the center of the pixel 3G-2.

In the pixel 3G-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 16) and 22a2 (upper right corner portion in FIG. 16) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 16) of the inter-pixel separation section 22. Furthermore, the selection transistor SEL is arranged on the side of the corner portion 22a4 (the lower right corner portion in FIG. 16) of the inter-pixel separation section 22. A contact 60 of a p-type well region is arranged at the center of the pixel 3G-3.

In the pixel 3G-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 16) and 22a4 (lower right corner portion in FIG. 16) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 16) of the inter-pixel separation section 22. Furthermore, the selection transistor SEL is arranged on the side of the corner portion 22a2 (the upper right corner portion in FIG. 16) of the inter-pixel separation section 22. A contact 60 of a p-type well region is arranged at the center of the pixel 3G-4.

### Functions and Effects of Second Modification of Second Embodiment

As described above, according to the second modification of the second embodiment, functions and effects similar to those of the above-described second embodiment can be obtained, and the phase difference detection information can be obtained in both the direction indicated by the arrow X in FIG. 16 and the direction indicated by the arrow Y in FIG. 16 for the same color from the output of each of the four pixels 3G-1, 3G-2, 3G-3, and 3G-4. This makes it possible to realize high performance image plane phase difference autofocus.

### Third Modification of Second Embodiment

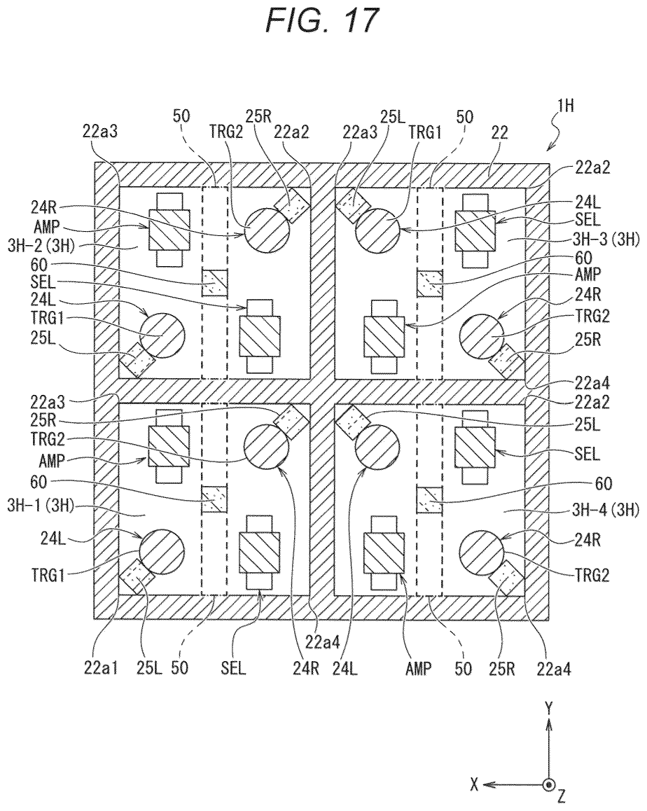

FIG. 17 is a plan view illustrating an arrangement relationship of a plurality of pixels 3H of a photodetection device 1H according to the third modification of the second embodiment of the present disclosure. In FIG. 17, the same portions as those in above FIG. 14 are denoted by the same reference signs, and a detailed description thereof is omitted.

In the pixel 3H-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 17) and 22a2 (upper right corner portion in FIG. 17) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 17) of the inter-pixel separation section 22. Furthermore, the selection transistor SEL is arranged on the side of the corner portion 22a4 (the lower right corner portion in FIG. 17) of the inter-pixel separation section 22. A contact 60 of a p-type well region is arranged at the center of the pixel 3H-1. Note that the pixel 3H-2 has the same arrangement configuration as the pixel 3H-1.

In the pixel 3H-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 17) and 22a4 (lower right corner portion in FIG. 17) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 17) of the inter-pixel separation section 22. Furthermore, the selection transistor SEL is arranged on the side of the corner portion 22a2 (the lower right corner portion in FIG. 17) of the inter-pixel separation section 22. A contact 60 of a p-type well region is arranged at the center of the pixel 3H-3. Note that the pixel 3H-4 has the same arrangement configuration as the pixel 3H-3.

In the third modification of the second embodiment of the present disclosure, the first charge accumulation region 25L and the second charge accumulation region 25R can be collectively arranged and shared in one place between the two adjacent pixels 3H-1 and 3H-4.

Furthermore, the first charge accumulation region 25L and the second charge accumulation region 25R can be collectively arranged and shared in one place between the two adjacent pixels 3H-2 and 3H-3.

### Functions and Effects of Third Modification of Second Embodiment

As described above, according to the third modification of the second embodiment, functions and effects similar to those of the above-described second embodiment and the second modification of the second embodiment can be obtained.

### Fourth Modification of Second Embodiment

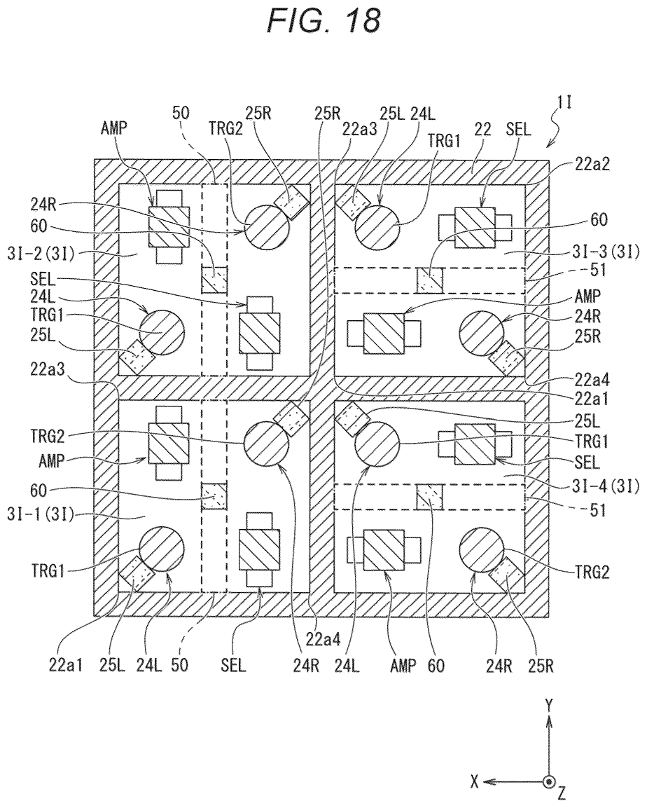

FIG. 18 is a plan view illustrating an arrangement relationship of a plurality of pixels 3I of a photodetection device 1I according to the fourth modification of the second embodiment of the present disclosure. In FIG. 18, the same portions as those in above FIG. 16 are denoted by the same reference signs, and a detailed description thereof is omitted.

In the pixel 3I-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 18) and 22a2 (upper right corner portion in FIG. 18) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 18) of the inter-pixel separation section 22. Furthermore, the selection transistor SEL is arranged on the side of the corner portion 22a4 (the lower right corner portion in FIG. 18) of the inter-pixel separation section 22. A contact 60 of a p-type well region is arranged at the center of the pixel 3I-1. Note that the pixel 3I-2 has the same arrangement configuration as the pixel 3I-1.

In the pixel 3I-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 18) and 22a4 (lower right corner portion in FIG. 18) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 18) of the inter-pixel separation section 22. Furthermore, the selection transistor SEL is arranged on the side of the corner portion 22a2 (the lower right corner portion in FIG. 18) of the inter-pixel separation section 22. A contact 60 of a p-type well region is arranged at the center of the pixel 3I-3. Note that the pixel 3I-4 has the same arrangement configuration as the pixel 3I-3.

In the fourth modification of the second embodiment of the present disclosure, the first charge accumulation region 25L and the second charge accumulation region 25R can be collectively arranged and shared in one place between the two adjacent pixels 3I-1 and 3I-4.

Furthermore, the first charge accumulation region 25L and the second charge accumulation region 25R can be collectively arranged and shared in one place between the two adjacent pixels 3I-2 and 3I-3.

### Functions and Effects of Fourth Modification of Second Embodiment

As described above, according to the fourth modification of the second embodiment, functions and effects similar to those of the above-described second embodiment and the second modification of the second embodiment can be obtained.

### Third Embodiment

In the third embodiment of the present disclosure, the first charge accumulation region 25L and the second charge accumulation region 25R do not face each other via the inter-pixel separation section 22.

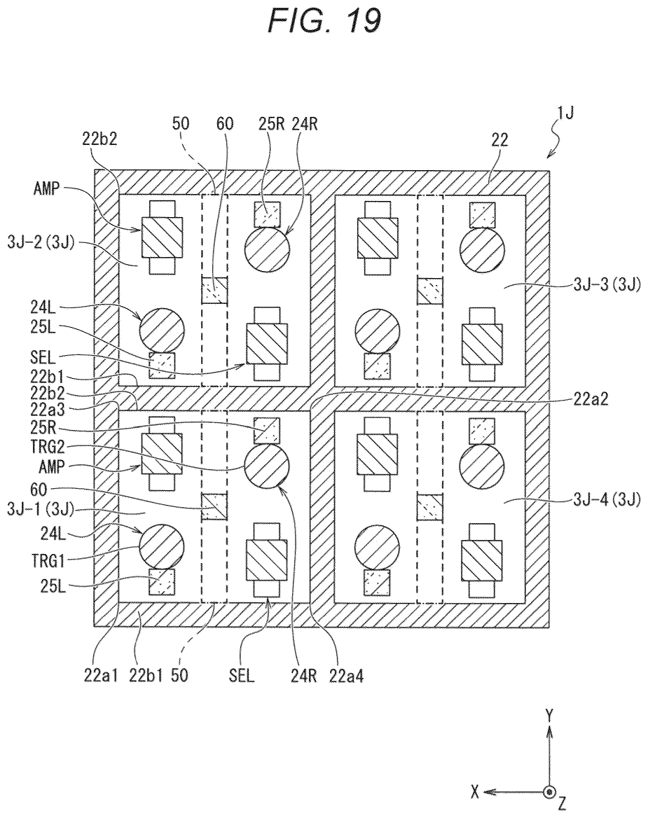

FIG. 19 is a plan view illustrating an arrangement relationship of a plurality of pixels 3E of a photodetection device 1E according to the third embodiment of the present disclosure. In FIG. 19, the same portions as those in above FIG. 9 are denoted by the same reference signs, and a detailed description thereof is omitted.

In the pixel 3E-1, the vertical gate electrode TRG1 of the first transfer transistor 24L and the vertical gate electrode TRG2 of the second transfer transistor 24R are arranged along a diagonal line connecting two corner portions 22a1 and 22a2 of the inter-pixel separation section 22 with the intra-pixel separation section 50 interposed therebetween. The first charge accumulation region 25L is arranged between the vertical gate electrode TRG1 of the first transfer transistor 24L and the side portion 22b1 of the inter-pixel separation section 22. The second charge accumulation region 25R is arranged between the vertical gate electrode TRG2 of the second transfer transistor 24R and the side portion 22b2 of the inter-pixel separation section 22.

The second charge accumulation region 25R is arranged to face the selection transistor SEL of the adjacent pixel 3J-2 so as not to face the first charge accumulation region 25L of the adjacent pixel 3J-2. Similarly, the first charge accumulation region 25L is arranged to face the amplification transistor AMP of the adjacent pixel 3J so as not to face the second charge accumulation region 25R of the adjacent pixel 3J.

The amplification transistor AMP is arranged on the side of the corner portion 22a3 (the upper left corner portion in FIG. 19) of the inter-pixel separation section 22. Furthermore, the selection transistor SEL is arranged on the side of the corner portion 22a4 (the lower right corner portion in FIG. 19) of the inter-pixel separation section 22. The contact 60 of the p-type well region is arranged at the center of the pixel 3E-1 on the first surface S1 side of the intra-pixel separation section 50. Note that the arrangement structure of the pixels 3-2, 3-3, and 3-4 is similar to that of the pixel 3-1.

### Functions and Effects of Third Embodiment

As described above, according to the third embodiment, functions and effects similar to those of the above-described second embodiment can be obtained, and the first charge accumulation region 25L and the second charge accumulation region 25R of the pixel 3J-1 are arranged so as not to face the first charge accumulation region 25L and the second charge accumulation region 25R of the adjacent pixel 3J via the inter-pixel separation section 22, whereby crosstalk between the plurality of first charge accumulation regions 25L and the second charge accumulation region 25R can be suppressed.

### First Modification of Third Embodiment

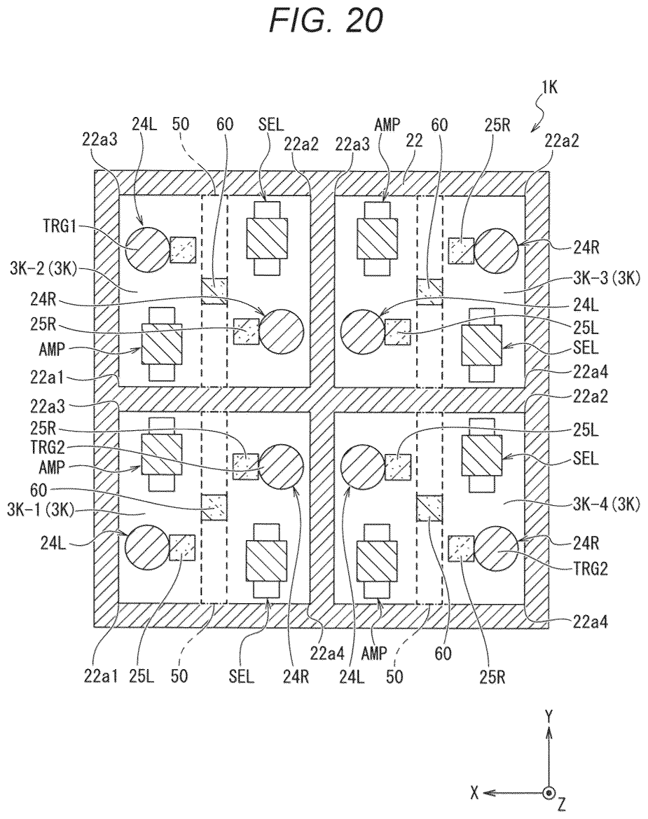

FIG. 20 is a plan view illustrating an arrangement relationship of a plurality of pixels 3K of a photodetection device 1K according to the first modification of the third embodiment of the present disclosure. In FIG. 20, the same portions as those in above FIG. 19 are denoted by the same reference signs, and a detailed description thereof is omitted.

In the pixel 3K-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 20) and 22a2 (upper right corner portion in FIG. 20) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a3 (the upper left corner portion in FIG. 20) of the inter-pixel separation section 22. Furthermore, the selection transistor SEL is arranged on the side of the corner portion 22a4 (the lower right corner portion in FIG. 20) of the inter-pixel separation section 22. A contact 60 of a p-type well region is arranged at the center of the pixel 3K-1.

In the pixel 3K-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 20) and 22a4 (lower right corner portion in FIG. 20) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a1 (the lower left corner portion in FIG. 20) of the inter-pixel separation section 22. Furthermore, the selection transistor SEL is arranged on the side of the corner portion 22a2 (the upper right corner portion in FIG. 20) of the inter-pixel separation section 22. A contact 60 of a p-type well region is arranged at the center of the pixel 3K-2.

In the pixel 3K-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 20) and 22a2 (upper right corner portion in FIG. 20) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a3 (the upper left corner portion in FIG. 20) of the inter-pixel separation section 22. Furthermore, the selection transistor SEL is arranged on the side of the corner portion 22a4 (the lower right corner portion in FIG. 20) of the inter-pixel separation section 22. A contact 60 of a p-type well region is arranged at the center of the pixel 3K-3.

In the pixel 3K-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 20) and 22a4 (lower right corner portion in FIG. 20) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a1 (the lower left corner portion in FIG. 20) of the inter-pixel separation section 22. Furthermore, the selection transistor SEL is arranged on the side of the corner portion 22a2 (the upper right corner portion in FIG. 20) of the inter-pixel separation section 22. A contact 60 of a p-type well region is arranged at the center of the pixel 3K-4.

Note that, in the second modification, the reset transistor RST may be arranged other than the amplification transistor AMP and the selection transistor SEL, and a conversion efficiency switching transistor FDG may be arranged in addition to the reset transistor RST.

### Functions and Effects of First Modification of Third Embodiment

As described above, according to the first modification of the third embodiment, functions and effects similar to those of the above-described second embodiment can be obtained, and the first charge accumulation region 25L and the second charge accumulation region 25R are arranged so as not to face each other via the intra-pixel separation section 50, whereby crosstalk between the first charge accumulation region 25L and the second charge accumulation region 25R can be suppressed.

### Second Modification of Third Embodiment

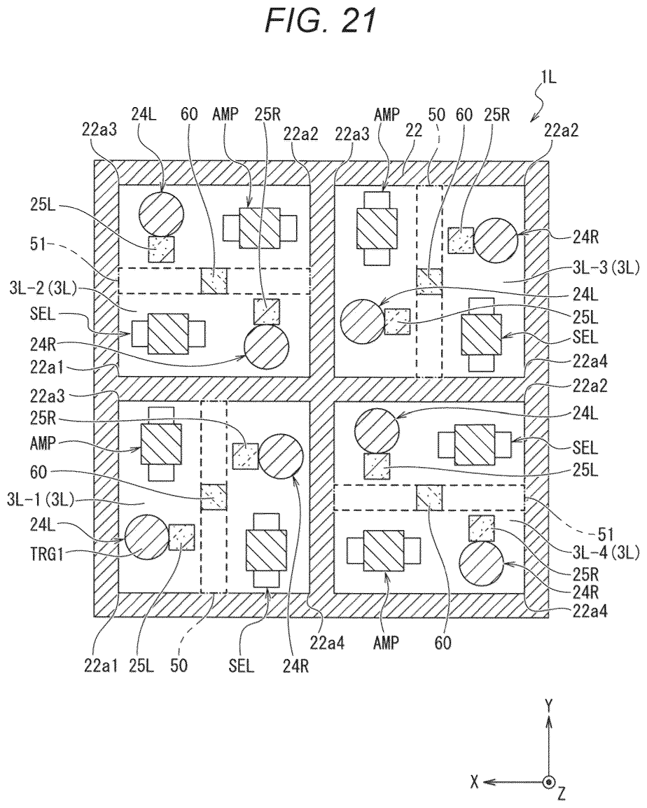

FIG. 21 is a plan view illustrating an arrangement relationship of a plurality of pixels 3L of a photodetection device 1L according to the second modification of the third embodiment of the present disclosure. In FIG. 21, the same portions as those in above FIG. 19 are denoted by the same reference signs, and a detailed description thereof is omitted.

In the second modification, the intra-pixel separation section 50 of the pixel 3L-1 extends in the direction indicated by the arrow Y in FIG. 21, and the intra-pixel separation section 51 of the pixel 3L-2 extends in the direction indicated by the arrow X in FIG. 21 rotated by 90° with respect to the intra-pixel separation section 50. Similarly, the intra-pixel separation section 50 of the pixel 3L-3 extends in the direction indicated by the arrow Y in FIG. 21, and the intra-pixel separation section 51 of the pixel 3L-4 extends in the direction indicated by the arrow X in FIG. 21 rotated by 90° with respect to the intra-pixel separation section 50.

In the pixel 3L-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 21) and 22a2 (upper right corner portion in FIG. 21) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a3 (the upper left corner portion in FIG. 21) of the inter-pixel separation section 22. Furthermore, the selection transistor SEL is arranged on the side of the corner portion 22a4 (the lower right corner portion in FIG. 21) of the inter-pixel separation section 22. A contact 60 of a p-type well region is arranged at the center of the pixel 3L-1.

In the pixel 3L-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 21) and 22a4 (lower right corner portion in FIG. 21) of the inter-pixel separation section 22 across the intra-pixel separation section 51. The first charge accumulation region 25L is arranged between the vertical gate electrode TRG1 of the first transfer transistor 24L and the intra-pixel separation section 51 so as to face the selection transistor SEL. The second charge accumulation region 25R is arranged between the vertical gate electrode TRG2 of the second transfer transistor 24R and the intra-pixel separation section 51 so as to face the amplification transistor AMP.

The selection transistor SEL is arranged on the side of the corner portion 22a1 (the lower left corner portion in FIG. 21) of the inter-pixel separation section 22. Furthermore, the amplification transistor AMP is arranged on the side of the corner portion 22a2 (the upper right corner portion in FIG. 21) of the inter-pixel separation section 22. A contact 60 of a p-type well region is arranged at the center of the pixel 3L-2.

In the pixel 3L-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 21) and 22a2 (upper right corner portion in FIG. 21) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a3 (the upper left corner portion in FIG. 21) of the inter-pixel separation section 22. Furthermore, the selection transistor SEL is arranged on the side of the corner portion 22a4 (the lower right corner portion in FIG. 21) of the inter-pixel separation section 22. A contact 60 of a p-type well region is arranged at the center of the pixel 3L-3.

In the pixel 3L-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 21) and 22a4 (lower right corner portion in FIG. 21) of the inter-pixel separation section 22 across the intra-pixel separation section 51. The first charge accumulation region 25L is arranged between the vertical gate electrode TRG1 of the first transfer transistor 24L and the intra-pixel separation section 51 so as to face the amplification transistor AMP. The second charge accumulation region 25R is arranged between the vertical gate electrode TRG2 of the second transfer transistor 24R and the intra-pixel separation section 51 so as to face the selection transistor SEL.

The amplification transistor AMP is arranged on the side of the corner portion 22a1 (the lower left corner portion in FIG. 21) of the inter-pixel separation section 22. Furthermore, the selection transistor SEL is arranged on the side of the corner portion 22a2 (the upper right corner portion in FIG. 21) of the inter-pixel separation section 22. A contact 60 of a p-type well region is arranged at the center of the pixel 3G-4.

### Functions and Effects of Second Modification of Third Embodiment

As described above, according to the second modification of the third embodiment, functions and effects similar to those of the above-described third embodiment can be obtained, and the phase difference detection information can be obtained in both the direction indicated by the arrow X in FIG. 21 and the direction indicated by the arrow Y in FIG. 21 for the same color from the output of each of the four pixels 3L-1, 3L-2, 3L-3, and 3L-4. This makes it possible to realize high performance image plane phase difference autofocus.

### Third Modification of Third Embodiment

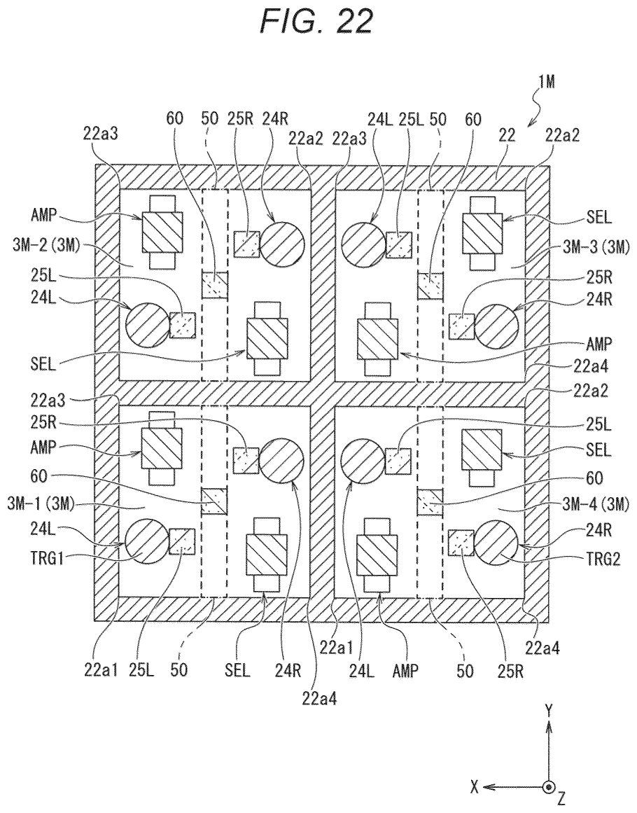

FIG. 22 is a plan view illustrating an arrangement relationship of a plurality of pixels 3M of a photodetection device 1M according to the third modification of the third embodiment of the present disclosure. In FIG. 22, the same portions as those in above FIG. 19 are denoted by the same reference signs, and a detailed description thereof is omitted.

In the pixel 3M-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 22) and 22a2 (upper right corner portion in FIG. 22) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a3 (the upper left corner portion in FIG. 22) of the inter-pixel separation section 22. Furthermore, the selection transistor SEL is arranged on the side of the corner portion 22a4 (the lower right corner portion in FIG. 22) of the inter-pixel separation section 22. A contact 60 of a p-type well region is arranged at the center of the pixel 3M-1. Note that the pixel 3M-2 has the same arrangement configuration as the pixel 3M-1.

In the pixel 3M-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 22) and 22a4 (lower right corner portion in FIG. 22) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a1 (the lower left corner portion in FIG. 22) of the inter-pixel separation section 22. Furthermore, the selection transistor SEL is arranged on the side of the corner portion 22a2 (the lower right corner portion in FIG. 22) of the inter-pixel separation section 22. A contact 60 of a p-type well region is arranged at the center of the pixel 3M-3. Note that the pixel 3M-4 has the same arrangement configuration as the pixel 3M-3.

### Functions and Effects of Third Modification of Third Embodiment

As described above, according to the third modification of the third embodiment, functions and effects similar to those of the above-described third embodiment and the second modification of the third embodiment can be obtained.

### Fourth Modification of Third Embodiment

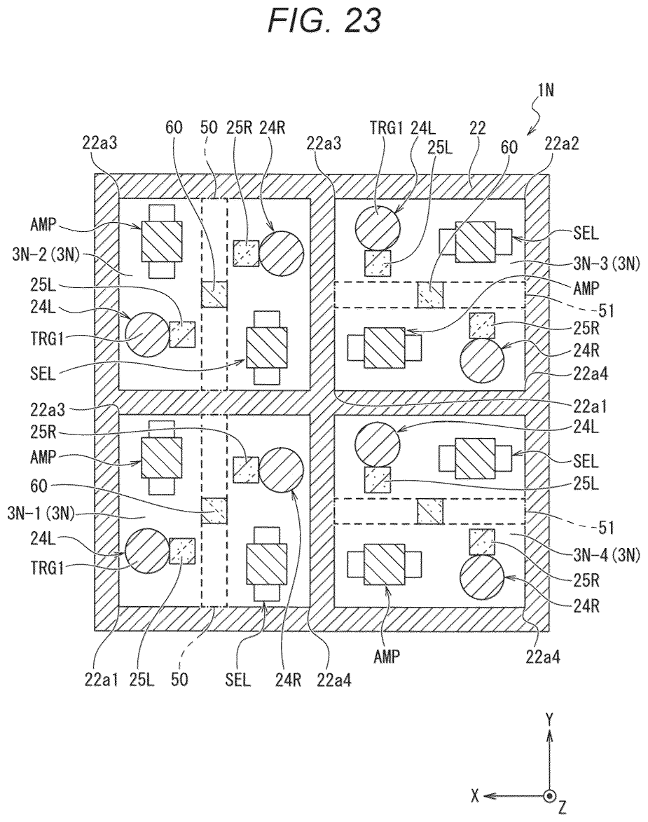

FIG. 23 is a plan view illustrating an arrangement relationship of a plurality of pixels 3N of a photodetection device 1N according to the fourth modification of the third embodiment of the present disclosure. In FIG. 23, the same portions as those in above FIG. 21 are denoted by the same reference signs, and a detailed description thereof is omitted.

In the pixel 3N-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 23) and 22a2 (upper right corner portion in FIG. 23) of the inter-pixel separation section 22 across the intra-pixel separation section 50. The first charge accumulation region 25L is arranged between the vertical gate electrode TRG1 of the first transfer transistor 24L and the intra-pixel separation section 50 so as to face the selection transistor SEL. The second charge accumulation region 25R is arranged between the vertical gate electrode TRG2 of the second transfer transistor 24R and the intra-pixel separation section 50 so as to face the amplification transistor AMP.

The amplification transistor AMP is arranged on the side of the corner portion 22a3 (the upper left corner portion in FIG. 23) of the inter-pixel separation section 22. Furthermore, the selection transistor SEL is arranged on the side of the corner portion 22a4 (the lower right corner portion in FIG. 23) of the inter-pixel separation section 22. A contact 60 of a p-type well region is arranged at the center of the pixel 3N-1. Note that the pixel 3N-2 has the same arrangement configuration as the pixel 3N-1.

In the pixel 3N-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 23) and 22a4 (lower right corner portion in FIG. 23) of the inter-pixel separation section 22 across the intra-pixel separation section 51. The first charge accumulation region 25L is arranged between the vertical gate electrode TRG1 of the first transfer transistor 24L and the intra-pixel separation section 51 so as to face the amplification transistor AMP. The second charge accumulation region 25R is arranged between the vertical gate electrode TRG2 of the second transfer transistor 24R and the intra-pixel separation section 51 so as to face the selection transistor SEL.

The amplification transistor AMP is arranged on the side of the corner portion 22a1 (the lower left corner portion in FIG. 23) of the inter-pixel separation section 22. Furthermore, the selection transistor SEL is arranged on the side of the corner portion 22a2 (the lower right corner portion in FIG. 23) of the inter-pixel separation section 22. A contact 60 of a p-type well region is arranged at the center of the pixel 3N-3. Note that the pixel 3N-4 has the same arrangement configuration as the pixel 3N-3.

### Functions and Effects of Fourth Modification of Third Embodiment

As described above, according to the fourth modification of the third embodiment, functions and effects similar to those of the above-described third embodiment and the second modification of the third embodiment can be obtained.

### Fourth Embodiment

In the fourth embodiment of the present disclosure, a part of the intra-pixel separation section 50 is formed by a full trench (FFTI) extending from a side portion of the inter-pixel separation section 22 (FFTI-Plugin structure).

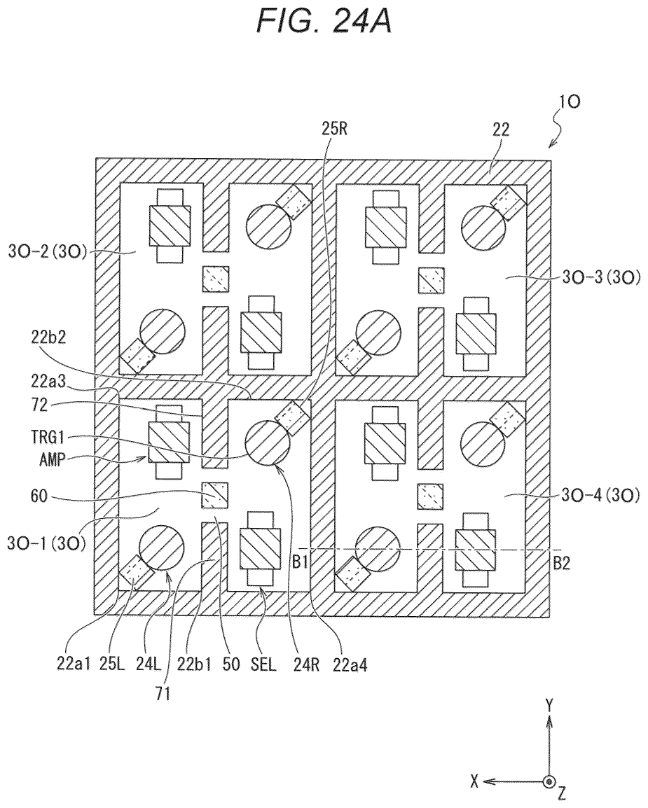

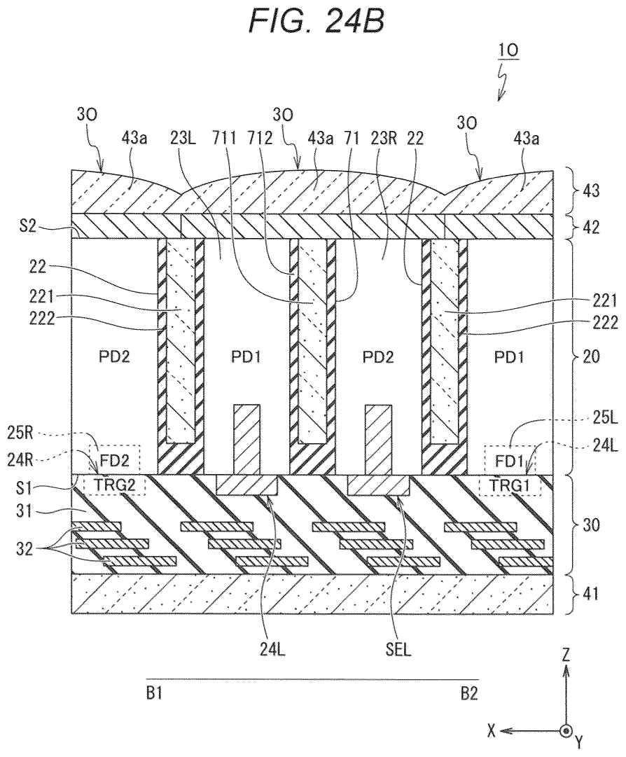

FIG. 24A is a plan view illustrating an arrangement relationship of a plurality of pixels 3E of a photodetection device 1O according to the fourth embodiment of the present disclosure. In FIG. 24A, the same portions as those in above FIG. 14 are denoted by the same reference signs, and a detailed description thereof is omitted. FIG. 24B is a partial longitudinal cross-sectional view illustrating an example of a laminated structure of the photodetection device 1O cut along an imaginary line B1-B2 illustrated in FIG. 24A.

In the pixel 3O-1, the vertical gate electrode TRG1 of the first transfer transistor 24L and the vertical gate electrode TRG2 of the second transfer transistor 24R are arranged along a diagonal line connecting two corner portions 22a1 and 22a2 of the inter-pixel separation section 22 with the intra-pixel separation section 50 interposed therebetween. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 24A) of the inter-pixel separation section 22. Furthermore, the selection transistor SEL is arranged on the side of the corner portion 22a4 (the lower right corner portion in FIG. 24A) of the inter-pixel separation section 22. The contact 60 of the p-type well region is arranged at the center of the pixel 3O-1 on the first surface S1 side of the intra-pixel separation section 50.

The intra-pixel separation section 50 is provided with a separation region 71 extending from the side portion 22b1 of the inter-pixel separation section 22 to substantially the center of the pixel 3O-1. As illustrated in FIG. 24B, the separation region 71 has a full trench structure formed from the first surface (element formation surface) S1 to the second surface (light incident surface) S2 of the semiconductor layer 20, and includes a semiconductor region 221 or a dielectric into which an impurity having the first conductivity type is implanted, and an interface layer 712 covering the semiconductor region 711 or the periphery of the dielectric. A metal oxide film or silicon oxide (SiO2) is used for the interface layer 712. Furthermore, the intra-pixel separation section 50 is provided with a separation region 72 extending from the side portion 22b2 of the inter-pixel separation section 22 to substantially the center of the pixel 3O-1. The separation region 72 includes a full trench structure formed from the first surface S1 to the second surface S2 of the semiconductor layer 20. Note that the arrangement structure of the pixels 3O-2, 3O-3, and 3O-4 is similar to that of the pixel 3O-1.

### Functions and Effects of Fourth Embodiment

As described above, according to the fourth embodiment, functions and effects similar to those of the above-described first embodiment can be obtained, and the separation regions 71 and 72 having the full trench structure are provided in a part of the intra-pixel separation section 50. Therefore, it is possible to suppress the generated signal charge from moving between the first photoelectric conversion section 23L and the second photoelectric conversion section 23R via the separation regions 71 and 72, and it is possible to improve the phase difference detection accuracy.

### First Modification of Fourth Embodiment

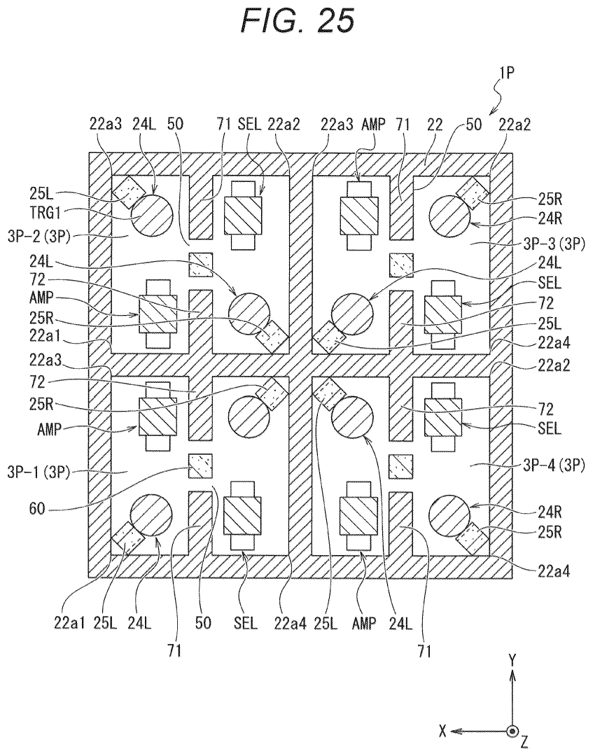

FIG. 25 is a plan view illustrating an arrangement relationship of a plurality of pixels 3P of a photodetection device 1P according to the first modification of the fourth embodiment of the present disclosure. In FIG. 25, the same portions as those in above FIG. 24A are denoted by the same reference signs, and a detailed description thereof is omitted.

In the pixel 3P-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 25) and 22a2 (upper right corner portion in FIG. 25) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 25) of the inter-pixel separation section 22. Furthermore, the selection transistor SEL is arranged on the side of the corner portion 22a4 (the lower right corner portion in FIG. 25) of the inter-pixel separation section 22. A contact 60 of a p-type well region is arranged at the center of the pixel 3P-1.

In the pixel 3P-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 25) and 22a4 (lower right corner portion in FIG. 25) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 25) of the inter-pixel separation section 22. Furthermore, the selection transistor SEL is arranged on the side of the corner portion 22a2 (the upper right corner portion in FIG. 25) of the inter-pixel separation section 22. A contact 60 of a p-type well region is arranged at the center of the pixel 3P-2.

In the pixel 3P-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 25) and 22a2 (upper right corner portion in FIG. 25) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 25) of the inter-pixel separation section 22. Furthermore, the selection transistor SEL is arranged on the side of the corner portion 22a4 (the lower right corner portion in FIG. 25) of the inter-pixel separation section 22. A contact 60 of a p-type well region is arranged at the center of the pixel 3P-3.

In the pixel 3P-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 25) and 22a4 (lower right corner portion in FIG. 25) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 25) of the inter-pixel separation section 22. Furthermore, the selection transistor SEL is arranged on the side of the corner portion 22a2 (the upper right corner portion in FIG. 25) of the inter-pixel separation section 22. A contact 60 of a p-type well region is arranged at the center of the pixel 3F-4.

In the first modification of the fourth embodiment of the present disclosure, the first charge accumulation region 25L and the second charge accumulation region 25R can be collectively arranged and shared in one place between the four adjacent pixels 3P-1, 3P-2, 3P-3, and 3P-4.

Furthermore, the separation regions 71 and 72 having a full trench structure are provided in the intra-pixel separation sections 50 of the respective pixels 3P-1, 3P-2, 3P-3, and 3P-4.

Note that, in the second modification, in a case where the first charge accumulation region 25L and the second charge accumulation region 25R are shared among the four pixels 3P-1, 3P-2, 3P-3, and 3P-4, at least one amplification transistor AMP and at least one selection transistor SEL are only required to be provided. In addition, a reset transistor RST may be arranged other than the amplification transistor AMP and the selection transistor SEL, and a conversion efficiency switching transistor FDG may be arranged other than the reset transistor RST.

### Functions and Effects of First Modification of Fourth Embodiment

As described above, according to the first modification of the fourth embodiment, functions and effects similar to those of the above-described fourth embodiment can be obtained, and the first charge accumulation region 25L and the second charge accumulation region 25R can be collectively arranged in one place between the four adjacent pixels 3P-1, 3P-2, 3P-3, and 3P-4, so that the layout efficiency is improved.

### Second Modification of Fourth Embodiment

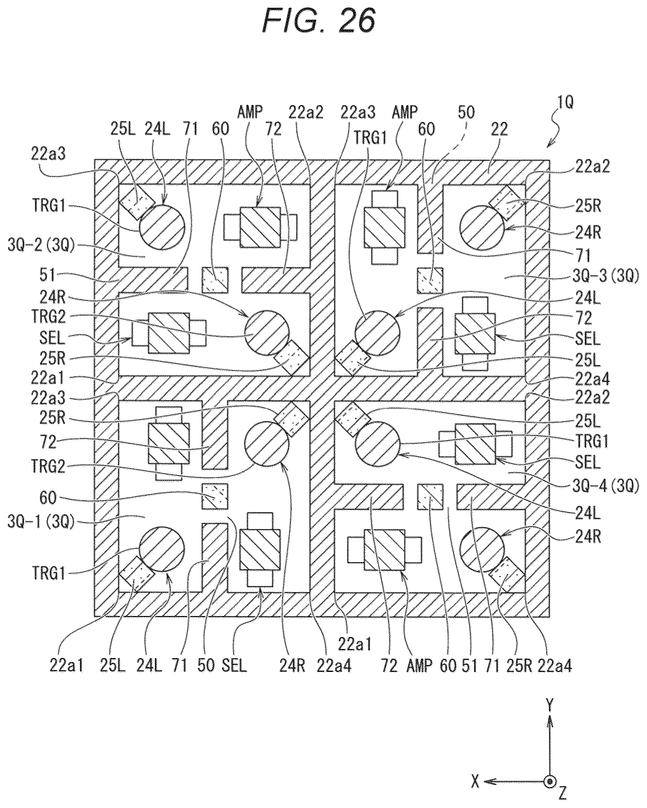

FIG. 26 is a plan view illustrating an arrangement relationship of a plurality of pixels 3Q of a photodetection device 1Q according to the second modification of the fourth embodiment of the present disclosure. In FIG. 26, the same portions as those in above FIG. 24A are denoted by the same reference signs, and a detailed description thereof is omitted.

In the second modification, the intra-pixel separation section 50 of the pixel 3Q-1 extends in the direction indicated by the arrow Y in FIG. 26, and the intra-pixel separation section 51 of the pixel 3Q-2 extends in the direction indicated by the arrow X in FIG. 26 rotated by 90° with respect to the intra-pixel separation section 50. Similarly, the intra-pixel separation section 50 of the pixel 3Q-3 extends in the direction indicated by the arrow Y in FIG. 26, and the intra-pixel separation section 51 of the pixel 3Q-4 extends in the direction indicated by the arrow X in FIG. 26 rotated by 90° with respect to the intra-pixel separation section 50.

In the pixel 3Q-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 26) and 22a2 (upper right corner portion in FIG. 26) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 26) of the inter-pixel separation section 22. Furthermore, the selection transistor SEL is arranged on the side of the corner portion 22a4 (the lower right corner portion in FIG. 26) of the inter-pixel separation section 22. A contact 60 of a p-type well region is arranged at the center of the pixel 3Q-1.

In the pixel 3Q-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 26) and 22a4 (lower right corner portion in FIG. 26) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The selection transistor SEL is arranged on the side of the corner portion 22a1 (the lower left corner portion in FIG. 26) of the inter-pixel separation section 22. Furthermore, the amplification transistor AMP is arranged on the side of the corner portion 22a2 (the upper right corner portion in FIG. 26) of the inter-pixel separation section 22. A contact 60 of a p-type well region is arranged at the center of the pixel 3Q-2.

In the pixel 3Q-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 26) and 22a2 (upper right corner portion in FIG. 26) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 26) of the inter-pixel separation section 22. Furthermore, the selection transistor SEL is arranged on the side of the corner portion 22a4 (the lower right corner portion in FIG. 26) of the inter-pixel separation section 22. A contact 60 of a p-type well region is arranged at the center of the pixel 3Q-3.

In the pixel 3Q-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 26) and 22a4 (lower right corner portion in FIG. 26) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 26) of the inter-pixel separation section 22. Furthermore, the selection transistor SEL is arranged on the side of the corner portion 22a2 (the upper right corner portion in FIG. 26) of the inter-pixel separation section 22. A contact 60 of a p-type well region is arranged at the center of the pixel 3Q-4.

Furthermore, the separation regions 71 and 72 having a full trench structure are provided in the intra-pixel separation section 50 of each of the pixels 3Q-1 and 3Q-3. Furthermore, the separation regions 71 and 72 having a full trench structure are provided in the intra-pixel separation section 51 of each of the pixels 3Q-2 and 3Q-4.

### Functions and Effects of Second Modification of Fourth Embodiment

As described above, according to the second modification of the fourth embodiment, functions and effects similar to those of the above-described fourth embodiment can be obtained, and the phase difference detection information can be obtained in both the direction indicated by the arrow X in FIG. 26 and the direction indicated by the arrow Y in FIG. 26 for the same color from the output of each of the four pixels 3Q-1, 3Q-2, 3Q-3, and 3Q-4. This makes it possible to realize high performance image plane phase difference autofocus.

### Third Modification of Fourth Embodiment

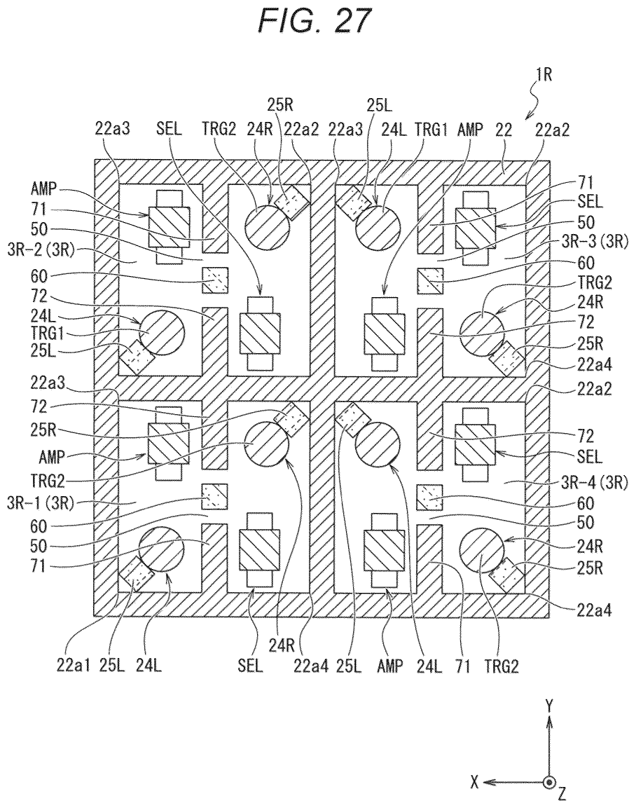

FIG. 27 is a plan view illustrating an arrangement relationship of a plurality of pixels 3R of a photodetection device 1R according to the third modification of the fourth embodiment of the present disclosure. In FIG. 27, the same portions as those in above FIG. 24A are denoted by the same reference signs, and a detailed description thereof is omitted.

In the pixel 3R-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 27) and 22a2 (upper right corner portion in FIG. 27) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 27) of the inter-pixel separation section 22. Furthermore, the selection transistor SEL is arranged on the side of the corner portion 22a4 (the lower right corner portion in FIG. 27) of the inter-pixel separation section 22. A contact 60 of a p-type well region is arranged at the center of the pixel 3R-1. Note that the pixel 3R-2 has the same arrangement configuration as the pixel 3R-1.

In the pixel 3R-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 27) and 22a4 (lower right corner portion in FIG. 27) of the inter-pixel separation section 22 across the intra-pixel separation section 50. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 27) of the inter-pixel separation section 22. Furthermore, the selection transistor SEL is arranged on the side of the corner portion 22a2 (the lower right corner portion in FIG. 27) of the inter-pixel separation section 22. A contact 60 of a p-type well region is arranged at the center of the pixel 3R-3. Note that the pixel 3R-4 has the same arrangement configuration as the pixel 3R-3.

In the third modification of the fourth embodiment of the present disclosure, the first charge accumulation region 25L and the second charge accumulation region 25R can be collectively arranged and shared in one place between the two adjacent pixels 3R-1 and 3R-4.

Furthermore, the first charge accumulation region 25L and the second charge accumulation region 25R can be collectively arranged and shared in one place between the two adjacent pixels 3R-2 and 3R-3.

Furthermore, the separation regions 71 and 72 having a full trench structure are provided in the intra-pixel separation section 50 of each of the pixels 3R-1, 3R-2, 3R-3, and 3R-4.

### Functions and Effects of Third Modification of Fourth Embodiment

As described above, according to the third modification of the fourth embodiment, functions and effects similar to those of the above-described fourth embodiment and the second modification of the fourth embodiment can be obtained.

### Fourth Modification of Fourth Embodiment

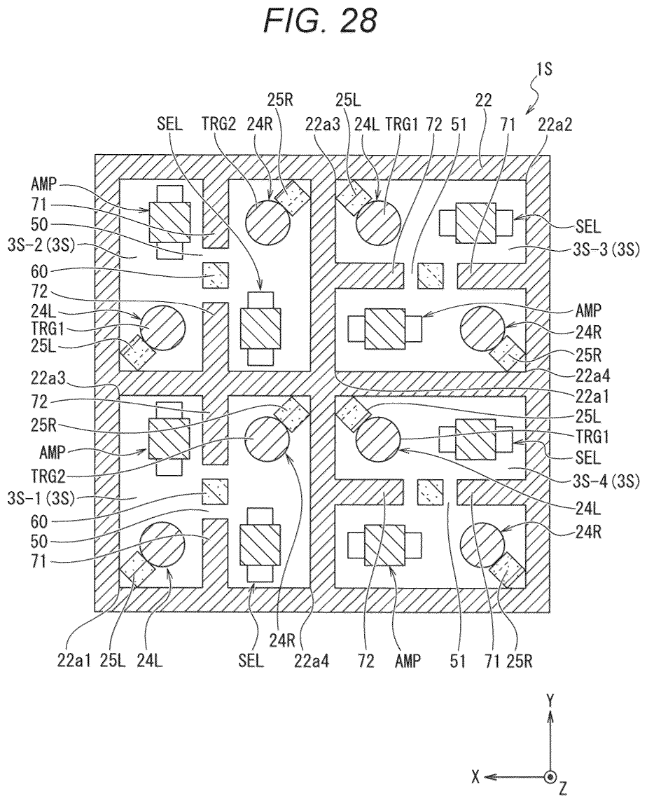

FIG. 28 is a plan view illustrating an arrangement relationship of a plurality of pixels 3S of a photodetection device 1S according to the fourth modification of the fourth embodiment of the present disclosure. In FIG. 28, the same portions as those in above FIG. 26 are denoted by the same reference signs, and a detailed description thereof is omitted.

In the pixel 3S-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 28) and 22a2 (upper right corner portion in FIG. 28) of the inter-pixel separation section 22 across the intra-pixel separation section 50. The first charge accumulation region 25L is arranged between the vertical gate electrode TRG1 of the first transfer transistor 24L and the corner portion 22a1. The second charge accumulation region 25R is arranged between the vertical gate electrode TRG2 of the second transfer transistor 24R and the corner portion 22a2.

The amplification transistor AMP is arranged on the side of the corner portion 22a3 (the upper left corner portion in FIG. 28) of the inter-pixel separation section 22. Furthermore, the selection transistor SEL is arranged on the side of the corner portion 22a4 (the lower right corner portion in FIG. 28) of the inter-pixel separation section 22. A contact 60 of a p-type well region is arranged at the center of the pixel 3S-1. Note that the pixel 3S-2 has the same arrangement configuration as the pixel 3S-1.

In the pixel 3S-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 28) and 22a4 (lower right corner portion in FIG. 28) of the inter-pixel separation section 22 across the intra-pixel separation section 51. The first charge accumulation region 25L is arranged between the vertical gate electrode TRG1 of the first transfer transistor 24L and the corner portion 22a3. The second charge accumulation region 25R is arranged between the vertical gate electrode TRG2 of the second transfer transistor 24R and the corner portion 22a4.

The amplification transistor AMP is arranged on the side of the corner portion 22a1 (the lower left corner portion in FIG. 28) of the inter-pixel separation section 22. Furthermore, the selection transistor SEL is arranged on the side of the corner portion 22a2 (the lower right corner portion in FIG. 28) of the inter-pixel separation section 22. A contact 60 of a p-type well region is arranged at the center of the pixel 3S-3. Note that the pixel 3S-4 has the same arrangement configuration as the pixel 3S-3.

In the fourth modification of the fourth embodiment of the present disclosure, the first charge accumulation region 25L and the second charge accumulation region 25R can be collectively arranged and shared in one place between the two adjacent pixels 3S-1 and 3S-4.

Furthermore, the first charge accumulation region 25L and the second charge accumulation region 25R can be collectively arranged and shared in one place between the two adjacent pixels 3S-2 and 3S-3.

Furthermore, the separation regions 71 and 72 having a full trench structure are provided in the intra-pixel separation section 50 of each of the pixels 3R-1 and 3R-2. Furthermore, the separation regions 71 and 72 having a full trench structure are provided in the intra-pixel separation section 51 of each of the pixels 3R-3 and 3Q-4.

### Functions and Effects of Fourth Modification of Fourth Embodiment

As described above, according to the fourth modification of the fourth embodiment, functions and effects similar to those of the above-described fourth embodiment and the second modification of the fourth embodiment can be obtained.

### Fifth Embodiment

In the fifth embodiment of the present disclosure, the first charge accumulation region 25L and the second charge accumulation region 25R do not face each other via the inter-pixel separation section 22. Further, a part of the intra-pixel separation section 50 is formed by a full trench (FFTI) extending from a side portion of the inter-pixel separation section 22 (FFTI-Plugin structure).

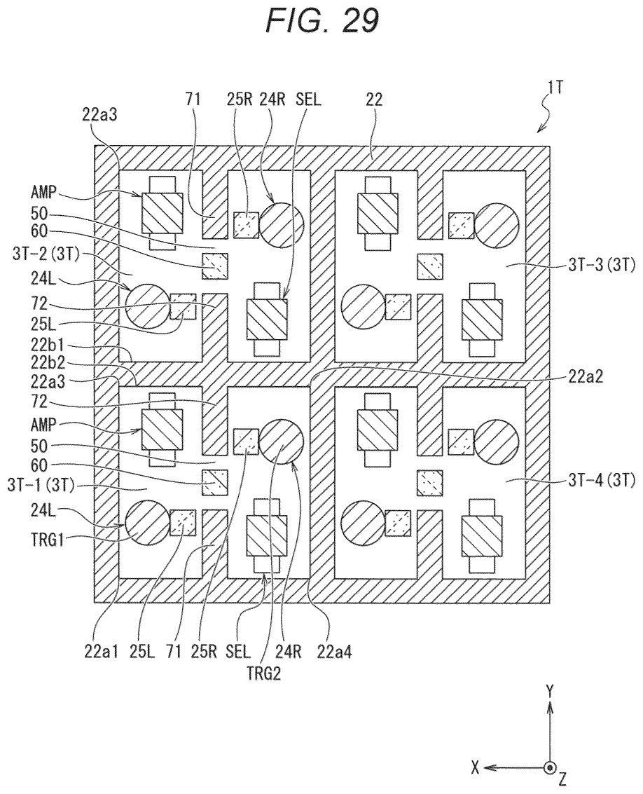

FIG. 29 is a plan view illustrating an arrangement relationship of a plurality of pixels 3T of a photodetection device 1T according to the fifth embodiment of the present disclosure. In FIG. 29, the same portions as those in above FIG. 24A are denoted by the same reference signs, and a detailed description thereof is omitted.

In the pixel 3T-1, the vertical gate electrode TRG1 of the first transfer transistor 24L and the vertical gate electrode TRG2 of the second transfer transistor 24R are arranged along a diagonal line connecting two corner portions 22a1 and 22a2 of the inter-pixel separation section 22 with the intra-pixel separation section 50 interposed therebetween. The first charge accumulation region 25L is arranged between the vertical gate electrode TRG1 of the first transfer transistor 24L and the separation region 71 of the intra-pixel separation section 50. The second charge accumulation region 25R is arranged between the vertical gate electrode TRG2 of the second transfer transistor 24R and the separation region 72 of the intra-pixel separation section 50.

The second charge accumulation region 25R is arranged to face the amplification transistor AMP. Similarly, the first charge accumulation region 25L is arranged to face the selection transistor SEL.

The amplification transistor AMP is arranged on the side of the corner portion 22a3 (the upper left corner portion in FIG. 29) of the inter-pixel separation section 22. Furthermore, the selection transistor SEL is arranged on the side of the corner portion 22a4 (the lower right corner portion in FIG. 29) of the inter-pixel separation section 22. The contact 60 of the p-type well region is arranged at the center of the pixel 3E-1 on the first surface S1 side of the intra-pixel separation section 50. Note that the arrangement structure of the pixels 3T-2, 3T-3, and 3T-4 is similar to that of the pixel 3T-1.

### Functions and Effects of Fifth Embodiment

As described above, according to the fifth embodiment, functions and effects similar to those of the above-described third embodiment and the fourth embodiment can be obtained.

### First Modification of Fifth Embodiment

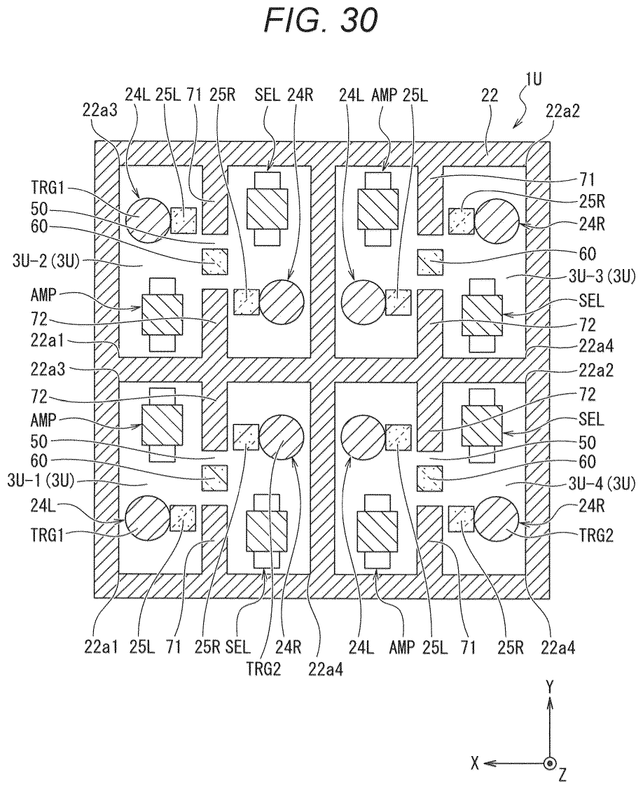

FIG. 30 is a plan view illustrating an arrangement relationship of a plurality of pixels 3U of a photodetection device 1U according to the first modification of the fifth embodiment of the present disclosure. In FIG. 30, the same portions as those in above FIG. 29 are denoted by the same reference signs, and a detailed description thereof is omitted.

In the pixel 3U-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 30) and 22a2 (upper right corner portion in FIG. 30) of the inter-pixel separation section 22 across the intra-pixel separation section 50. The first charge accumulation region 25L is arranged between the vertical gate electrode TRG1 of the first transfer transistor 24L and the separation region 71 of the intra-pixel separation section 50 so as to face the selection transistor SEL. The second charge accumulation region 25R is arranged between the vertical gate electrode TRG2 of the second transfer transistor 24R and the separation region 72 of the intra-pixel separation section 50 so as to face the amplification transistor AMP.

The amplification transistor AMP is arranged on the side of the corner portion 22a3 (the upper left corner portion in FIG. 30) of the inter-pixel separation section 22. Furthermore, the selection transistor SEL is arranged on the side of the corner portion 22a4 (the lower right corner portion in FIG. 30) of the inter-pixel separation section 22. A contact 60 of a p-type well region is arranged at the center of the pixel 3U-1.

In the pixel 3U-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 30) and 22a4 (lower right corner portion in FIG. 30) of the inter-pixel separation section 22 across the intra-pixel separation section 50. The first charge accumulation region 25L is arranged between the vertical gate electrode TRG1 of the first transfer transistor 24L and the separation region 71 of the intra-pixel separation section 50 so as to face the selection transistor SEL. The second charge accumulation region 25R is arranged between the vertical gate electrode TRG2 of the second transfer transistor 24R and the separation region 72 of the intra-pixel separation section 50 so as to face the amplification transistor AMP.

The amplification transistor AMP is arranged on the side of the corner portion 22a1 (the lower left corner portion in FIG. 30) of the inter-pixel separation section 22. Furthermore, the selection transistor SEL is arranged on the side of the corner portion 22a2 (the upper right corner portion in FIG. 30) of the inter-pixel separation section 22. A contact 60 of a p-type well region is arranged at the center of the pixel 3U-2.

In the pixel 3U-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 30) and 22a2 (upper right corner portion in FIG. 30) of the inter-pixel separation section 22 across the intra-pixel separation section 50. The first charge accumulation region 25L is arranged between the vertical gate electrode TRG1 of the first transfer transistor 24L and the separation region 72 of the intra-pixel separation section 50 so as to face the selection transistor SEL. The second charge accumulation region 25R is arranged between the vertical gate electrode TRG2 of the second transfer transistor 24R and the separation region 71 of the intra-pixel separation section 50 so as to face the amplification transistor AMP.

The amplification transistor AMP is arranged on the side of the corner portion 22a3 (the upper left corner portion in FIG. 30) of the inter-pixel separation section 22. Furthermore, the selection transistor SEL is arranged on the side of the corner portion 22a4 (the lower right corner portion in FIG. 30) of the inter-pixel separation section 22. A contact 60 of a p-type well region is arranged at the center of the pixel 3U-3.

In the pixel 3U-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 30) and 22a4 (lower right corner portion in FIG. 30) of the inter-pixel separation section 22 across the intra-pixel separation section 50. The first charge accumulation region 25L is arranged between the vertical gate electrode TRG1 of the first transfer transistor 24L and the separation region 72 of the intra-pixel separation section 50 so as to face the selection transistor SEL. The second charge accumulation region 25R is arranged between the vertical gate electrode TRG2 of the second transfer transistor 24R and the separation region 71 of the intra-pixel separation section 50 so as to face the amplification transistor AMP.

The amplification transistor AMP is arranged on the side of the corner portion 22a1 (the lower left corner portion in FIG. 30) of the inter-pixel separation section 22. Furthermore, the selection transistor SEL is arranged on the side of the corner portion 22a2 (the upper right corner portion in FIG. 30) of the inter-pixel separation section 22. A contact 60 of a p-type well region is arranged at the center of the pixel 3K-4.

Note that, in the second modification, the reset transistor RST may be arranged other than the amplification transistor AMP and the selection transistor SEL, and a conversion efficiency switching transistor FDG may be arranged in addition to the reset transistor RST.

### Functions and Effects of First Modification of Fifth Embodiment

As described above, according to the first modification of the fifth embodiment, functions and effects similar to those of the above-described fourth embodiment can be obtained, and the first charge accumulation region 25L and the second charge accumulation region 25R are arranged so as not to face each other via the intra-pixel separation section 50, whereby crosstalk between the first charge accumulation region 25L and the second charge accumulation region 25R can be suppressed.

### Second Modification of Fifth Embodiment

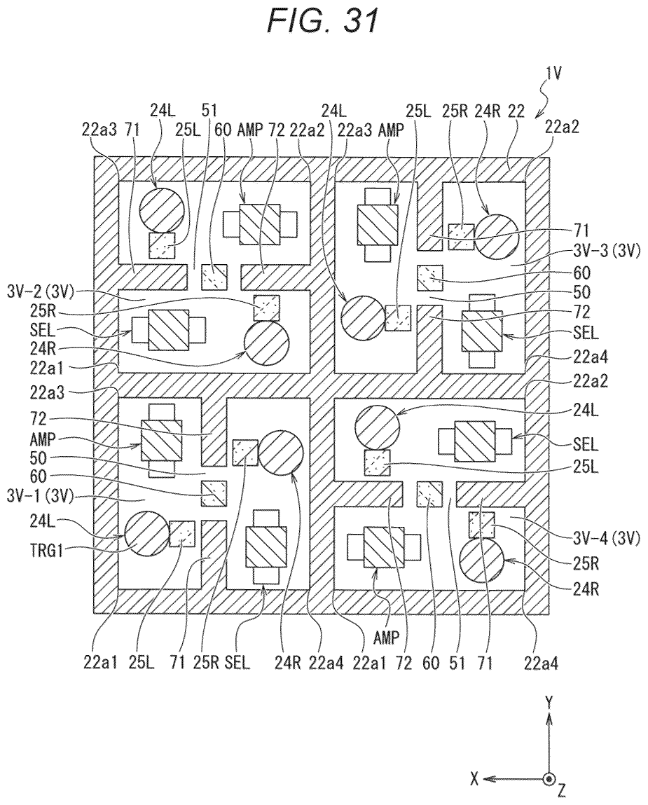

FIG. 31 is a plan view illustrating an arrangement relationship of a plurality of pixels 3V of a photodetection device 1V according to the second modification of the fifth embodiment of the present disclosure. In FIG. 31, the same portions as those in above FIG. 29 are denoted by the same reference signs, and a detailed description thereof is omitted.

In the second modification, the intra-pixel separation section 50 of the pixel 3V-1 extends in the direction indicated by the arrow Y in FIG. 31, and the intra-pixel separation section 51 of the pixel 3V-2 extends in the direction indicated by the arrow X in FIG. 31 rotated by 90° with respect to the intra-pixel separation section 50. Similarly, the intra-pixel separation section 50 of the pixel 3V-3 extends in the direction indicated by the arrow Y in FIG. 31, and the intra-pixel separation section 51 of the pixel 3V-4 extends in the direction indicated by the arrow X in FIG. 31 rotated by 90° with respect to the intra-pixel separation section 50.

In the pixel 3V-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 31) and 22a2 (upper right corner portion in FIG. 31) of the inter-pixel separation section 22 across the intra-pixel separation section 50. The first charge accumulation region 25L is arranged between the vertical gate electrode TRG1 of the first transfer transistor 24L and the separation region 71 of the intra-pixel separation section 50 so as to face the selection transistor SEL. The second charge accumulation region 25R is arranged between the vertical gate electrode TRG2 of the second transfer transistor 24R and the separation region 72 of the intra-pixel separation section 50 so as to face the amplification transistor AMP.

The amplification transistor AMP is arranged on the side of the corner portion 22a3 (the upper left corner portion in FIG. 31) of the inter-pixel separation section 22. Furthermore, the selection transistor SEL is arranged on the side of the corner portion 22a4 (the lower right corner portion in FIG. 31) of the inter-pixel separation section 22. A contact 60 of a p-type well region is arranged at the center of the pixel 3V-1.

In the pixel 3V-2, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 31) and 22a4 (lower right corner portion in FIG. 31) of the inter-pixel separation section 22 across the intra-pixel separation section 51. The first charge accumulation region 25L is arranged between the vertical gate electrode TRG1 of the first transfer transistor 24L and the separation region 71 of the intra-pixel separation section 51 so as to face the selection transistor SEL. The second charge accumulation region 25R is arranged between the vertical gate electrode TRG2 of the second transfer transistor 24R and the separation region 72 of the intra-pixel separation section 51 so as to face the amplification transistor AMP.

The selection transistor SEL is arranged on the side of the corner portion 22a1 (the lower left corner portion in FIG. 31) of the inter-pixel separation section 22. Furthermore, the amplification transistor AMP is arranged on the side of the corner portion 22a2 (the upper right corner portion in FIG. 31) of the inter-pixel separation section 22. A contact 60 of a p-type well region is arranged at the center of the pixel 3V-2.

In the pixel 3V-3, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 31) and 22a2 (upper right corner portion in FIG. 31) of the inter-pixel separation section 22 across the intra-pixel separation section 50. The first charge accumulation region 25L is arranged between the vertical gate electrode TRG1 of the first transfer transistor 24L and the separation region 72 of the intra-pixel separation section 50 so as to face the selection transistor SEL. The second charge accumulation region 25R is arranged between the vertical gate electrode TRG2 of the second transfer transistor 24R and the separation region 71 of the intra-pixel separation section 50 so as to face the amplification transistor AMP.

The amplification transistor AMP is arranged on the side of the corner portion 22a3 (the upper left corner portion in FIG. 31) of the inter-pixel separation section 22. Furthermore, the selection transistor SEL is arranged on the side of the corner portion 22a4 (the lower right corner portion in FIG. 31) of the inter-pixel separation section 22. A contact 60 of a p-type well region is arranged at the center of the pixel 3V-3.

In the pixel 3V-4, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 31) and 22a4 (lower right corner portion in FIG. 31) of the inter-pixel separation section 22 across the intra-pixel separation section 51. The first charge accumulation region 25L is arranged between the vertical gate electrode TRG1 of the first transfer transistor 24L and the separation region 72 of the intra-pixel separation section 51 so as to face the amplification transistor AMP. The second charge accumulation region 25R is arranged between the vertical gate electrode TRG2 of the second transfer transistor 24R and the separation region 71 of the intra-pixel separation section 51 so as to face the selection transistor SEL.

The amplification transistor AMP is arranged on the side of the corner portion 22a1 (the lower left corner portion in FIG. 31) of the inter-pixel separation section 22. Furthermore, the selection transistor SEL is arranged on the side of the corner portion 22a2 (the upper right corner portion in FIG. 31) of the inter-pixel separation section 22. A contact 60 of a p-type well region is arranged at the center of the pixel 3V-4.

### Functions and Effects of Second Modification of Fifth Embodiment

As described above, according to the second modification of the fifth embodiment, functions and effects similar to those of the above-described fifth embodiment can be obtained, and the phase difference detection information can be obtained in both the direction indicated by the arrow X in FIG. 31 and the direction indicated by the arrow Y in FIG. 31 for the same color from the output of each of the four pixels 3V-1, 3V-2, 3V-3, and 3V-4. This makes it possible to realize high performance image plane phase difference autofocus.

### Third Modification of Fifth Embodiment

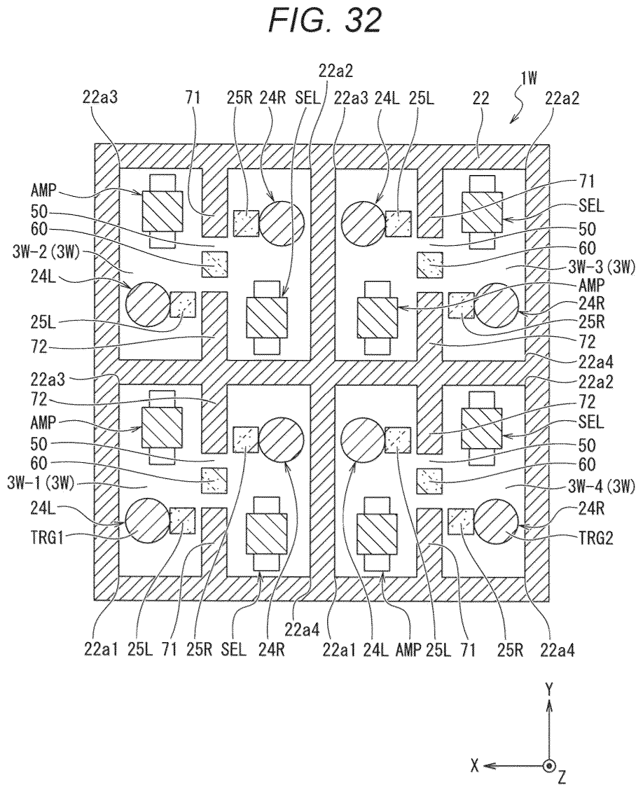

FIG. 32 is a plan view illustrating an arrangement relationship of a plurality of pixels 3W of a photodetection device 1W according to the third modification of the fifth embodiment of the present disclosure. In FIG. 32, the same portions as those in above FIG. 29 are denoted by the same reference signs, and a detailed description thereof is omitted.

In the pixel 3W-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 32) and 22a2 (upper right corner portion in FIG. 32) of the inter-pixel separation section 22 across the intra-pixel separation section 50. The first charge accumulation region 25L is arranged between the vertical gate electrode TRG1 of the first transfer transistor 24L and the separation region 71 of the intra-pixel separation section 50 so as to face the selection transistor SEL. The second charge accumulation region 25R is arranged between the vertical gate electrode TRG2 of the second transfer transistor 24R and the separation region 72 of the intra-pixel separation section 50 so as to face the amplification transistor AMP.

The amplification transistor AMP is arranged on the side of the corner portion 22a3 (the upper left corner portion in FIG. 32) of the inter-pixel separation section 22. Furthermore, the selection transistor SEL is arranged on the side of the corner portion 22a4 (the lower right corner portion in FIG. 32) of the inter-pixel separation section 22. A contact 60 of a p-type well region is arranged at the center of the pixel 3W-1. Note that the pixel 3W-2 has the same arrangement configuration as the pixel 3W-1.

In the pixel 3W-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 32) and 22a4 (lower right corner portion in FIG. 32) of the inter-pixel separation section 22 across the intra-pixel separation section 50. The first charge accumulation region 25L is arranged between the vertical gate electrode TRG1 of the first transfer transistor 24L and the separation region 71 of the intra-pixel separation section 50 so as to face the selection transistor SEL. The second charge accumulation region 25R is arranged between the vertical gate electrode TRG2 of the second transfer transistor 24R and the separation region 72 of the intra-pixel separation section 50 so as to face the amplification transistor AMP.

The amplification transistor AMP is arranged on the side of the corner portion 22a1 (the lower left corner portion in FIG. 32) of the inter-pixel separation section 22. Furthermore, the selection transistor SEL is arranged on the side of the corner portion 22a2 (the lower right corner portion in FIG. 32) of the inter-pixel separation section 22. A contact 60 of a p-type well region is arranged at the center of the pixel 3W-3. Note that the pixel 3W-4 has the same arrangement configuration as the pixel 3W-3.

### Functions and Effects of Third Modification of Fifth Embodiment

As described above, according to the third modification of the fifth embodiment, functions and effects similar to those of the above-described fifth embodiment and the second modification of the fifth embodiment can be obtained.

### Fourth Modification of Fifth Embodiment

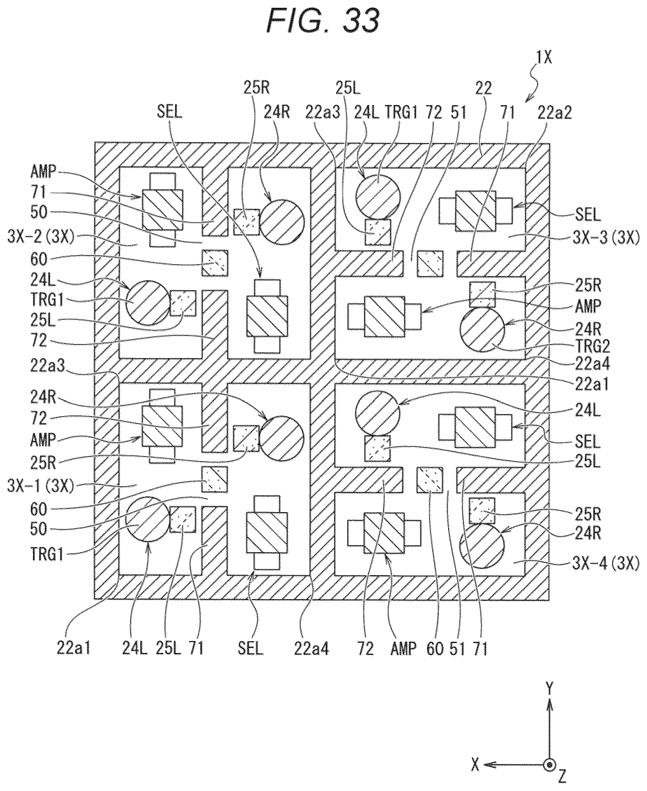

FIG. 33 is a plan view illustrating an arrangement relationship of a plurality of pixels 3X of a photodetection device 1X according to the fourth modification of the fifth embodiment of the present disclosure. In FIG. 33, the same portions as those in above FIG. 31 are denoted by the same reference signs, and a detailed description thereof is omitted.

In the pixel 3X-1, the vertical gate electrode TRG1 of the first transfer transistor 24L and the vertical gate electrode TRG2 of the second transfer transistor 24R are arranged along a diagonal line connecting two corner portions 22a1 (lower left corner portion in FIG. 33) and 22a2 (upper right corner portion in FIG. 33) of the inter-pixel separation section 22 across the intra-pixel separation section 50. The first charge accumulation region 25L is arranged between the vertical gate electrode TRG1 of the first transfer transistor 24L and the separation region 71 of the intra-pixel separation section 50 so as to face the selection transistor SEL. The second charge accumulation region 25R is arranged between the vertical gate electrode TRG2 of the second transfer transistor 24R and the separation region 72 of the intra-pixel separation section 50 so as to face the amplification transistor AMP.

The amplification transistor AMP is arranged on the side of the corner portion 22a3 (the upper left corner portion in FIG. 33) of the inter-pixel separation section 22. Furthermore, the selection transistor SEL is arranged on the side of the corner portion 22a4 (the lower right corner portion in FIG. 33) of the inter-pixel separation section 22. A contact 60 of a p-type well region is arranged at the center of the pixel 3X-1. Note that the pixel 3X-2 has the same arrangement configuration as the pixel 3X-1.

In the pixel 3X-3, the vertical gate electrode TRG1 of the first transfer transistor 24L and the vertical gate electrode TRG2 of the second transfer transistor 24R are arranged along a diagonal line connecting two corner portions 22a3 (upper left corner portion in FIG. 33) and 22a4 (lower right corner portion in FIG. 33) of the inter-pixel separation section 22 across the intra-pixel separation section 51. The first charge accumulation region 25L is arranged between the vertical gate electrode TRG1 of the first transfer transistor 24L and the separation region 72 of the intra-pixel separation section 51 so as to face the amplification transistor AMP. The second charge accumulation region 25R is arranged between the vertical gate electrode TRG2 of the second transfer transistor 24R and the separation region 71 of the intra-pixel separation section 51 so as to face the selection transistor SEL.

The amplification transistor AMP is arranged on the side of the corner portion 22a1 (the lower left corner portion in FIG. 33) of the inter-pixel separation section 22. Furthermore, the selection transistor SEL is arranged on the side of the corner portion 22a2 (the lower right corner portion in FIG. 33) of the inter-pixel separation section 22. A contact 60 of a p-type well region is arranged at the center of the pixel 3X-3. Note that the pixel 3X-4 has the same arrangement configuration as the pixel 3X-3.

### Functions and Effects of Fourth Modification of Fifth Embodiment

As described above, according to the fourth modification of the fifth embodiment, functions and effects similar to those of the above-described fifth embodiment and the second modification of the fifth embodiment can be obtained.

### Other Embodiments

As described above, the present technology has been described by the first embodiment, the first to fourth modifications of the first embodiment, the second embodiment, the first to fourth modifications of the second embodiment, the third embodiment, the first to fourth modifications of the third embodiment, the fourth embodiment, the first to fourth modifications of the fourth embodiment, the fifth embodiment, and the first to fourth modifications of the fifth embodiment. However, it should not be understood that the description and the drawings constituting a part of this disclosure limit the present technology. It will be apparent to those skilled in the art that various alternative embodiments, examples, and operation techniques can be included in the present technology when understanding the gist of the technical contents disclosed in the first embodiment, the first to fourth modifications of the first embodiment, the second embodiment, the first to fourth modifications of the second embodiment, the third embodiment, the first to fourth modifications of the third embodiment, the fourth embodiment, the first to fourth modifications of the fourth embodiment, the fifth embodiment, and the first to fourth modifications of the fifth embodiment described above. In addition, the configurations disclosed in the first embodiment, the first to fourth modifications of the first embodiment, the second embodiment, the first to fourth modifications of the second embodiment, the third embodiment, the first to fourth modifications of the third embodiment, the fourth embodiment, the first to fourth modifications of the fourth embodiment, the fifth embodiment, and the first to fourth modifications of the fifth embodiment can be appropriately combined within a range in which no contradiction occurs. For example, configurations disclosed in a plurality of different embodiments may be combined, or configurations disclosed in a plurality of different modifications of the same embodiment may be combined.

### Application Example to Electronic Apparatus

The photodetection device described above can be applied to various electronic apparatuses such as, for example, an imaging device such as a digital still camera and a digital video camera, a mobile phone with an imaging function, or other apparatuses having an imaging function.

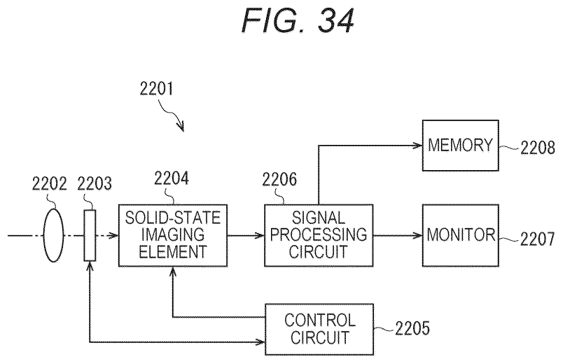

FIG. 34 is a block diagram illustrating a configuration example of an imaging device as an electronic apparatus to which the present technology is applied.

An imaging device 2201 illustrated in FIG. 34 includes an optical system 2202, a shutter device 2203, a solid-state imaging element 2204 as a photodetection device, a control circuit 2205, a signal processing circuit 2206, a monitor 2207, and two memories 2208, and can capture a still image and a moving image.

The optical system 2202 includes one or a plurality of lenses, and guides light from a subject (incident light) to the solid-state imaging element 2204 to form an image on a light receiving surface of the solid-state imaging element 2204.

The shutter device 2203 arranged between the optical system 2202 and the solid-state imaging element 2204 controls a light emission period to the solid-state imaging element 2204 and a light-shielding period according to control of the control circuit 2205.

The solid-state imaging element 2204 includes a package including the solid-state imaging element described above. The solid-state imaging element 2204 accumulates a signal charge for a certain period according to the light the image of which is formed as an image on the light receiving surface via the optical system 2202 and the shutter device 2203. The signal charges accumulated in the solid-state imaging element 2204 are transferred according to a drive signal (timing signal) supplied from the control circuit 2205.

The control circuit 2205 outputs the drive signal to control a transfer operation of the solid-state imaging element 2204 and a shutter operation of the shutter device 2203 to drive the solid-state imaging element 2204 and the shutter device 2203.

The signal processing circuit 2206 performs various types of signal processing on the signal charges output from the solid-state imaging element 2204. An image (image data) obtained by the signal processing circuit 2206 performing the signal processing is supplied to the monitor 2207 to be displayed or supplied to the memory 2208 to be stored (recorded).

Also in the imaging device 2201 configured as described above, the photodetection devices 1, 1A to 1X can be applied instead of the solid-state imaging element 2204 described above.

### Application Example to Mobile Body

The technology according to the present disclosure (the present technology) can be applied to various products. For example, the technology according to the present disclosure may be achieved as a device mounted on any type of mobile body such as an automobile, an electric vehicle, a hybrid electric vehicle, a motorcycle, a bicycle, a personal mobility, an airplane, a drone, a ship, a robot, and the like.

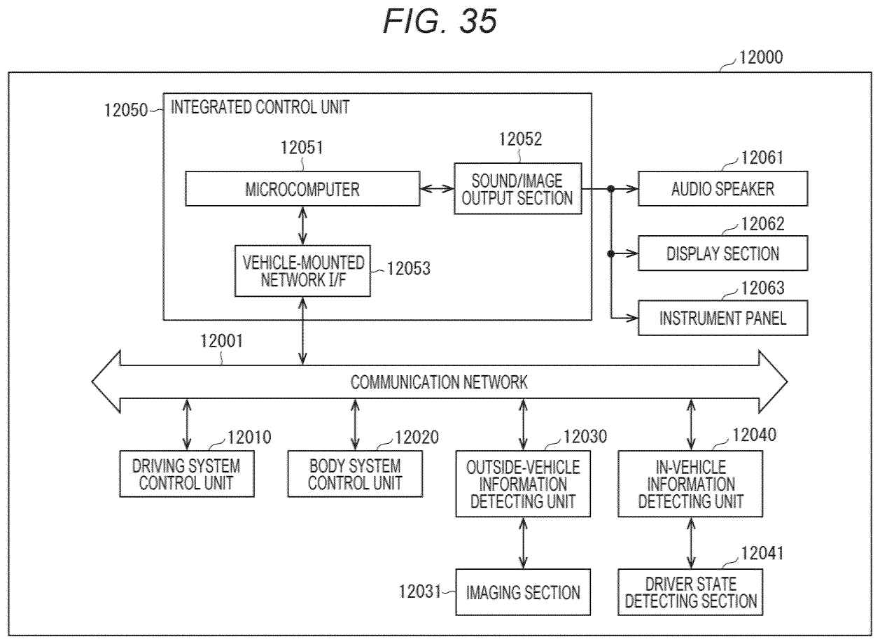

FIG. 35 is a block diagram depicting a schematic configuration example of a vehicle control system as an example of a mobile body control system to which the technology according to the present disclosure can be applied.

The vehicle control system 12000 includes a plurality of electronic control units connected to each other via a communication network 12001. In the example depicted in FIG. 35, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 35, an audio speaker 12061, a display section 12062, and an instrument panel 12063 are illustrated as the output device. The display section 12062 may, for example, include at least one of an on-board display and a head-up display.

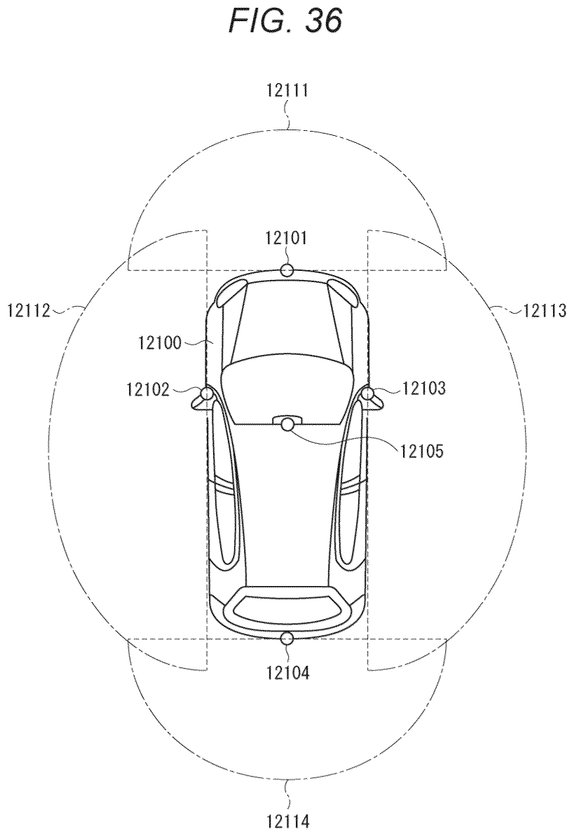

FIG. 36 is a diagram depicting an example of the installation position of the imaging section 12031.

In FIG. 36, the vehicle 12100 has imaging sections 12101, 12102, 12103, 12104, and 12105 as the imaging section 12031.

The imaging sections 12101, 12102, 12103, 12104, 12105 are provided, for example, at positions such as a front nose, a sideview mirror, a rear bumper, a back door, an upper portion of a windshield in the interior of a vehicle 12100, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The forward images obtained by the imaging sections 12101 and 12105 are used mainly to detect a preceding vehicle, a pedestrian, an obstacle, a traffic signal, a traffic sign, a lane, or the like.

Incidentally, FIG. 36 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 and the like, for example, among the configurations described above. Specifically, the technology can be applied to the photodetection device 1 in FIG. 1.

Note that the present disclosure can also have the following configurations.

(1)

A photodetection device including
a semiconductor layer including a plurality of pixels arranged in a matrix and having a light incident surface on which light is incident on the pixels,
each of the plurality of pixels including:
an inter-pixel separation section that defines an outer edge shape of the pixel, is formed by a full trench extending from a light incident surface of the semiconductor layer to an element surface on a side opposite to the light incident surface, and insulates and shields the pixel adjacent;
an intra-pixel separation section that separates the pixel into two;
a first photoelectric conversion section and a second photoelectric conversion section that are provided adjacent to each other via the intra-pixel separation section in plan view and generate a charge of an amount corresponding to light incident on the light incident surface, respectively;
a plurality of floating diffusion regions provided on the element surface of the semiconductor layer and temporarily accumulating the charge;
a first transfer transistor that transfers the charge generated by the first photoelectric conversion section to one of the plurality of floating diffusion regions; and
a second transfer transistor that transfers the charge generated by the second photoelectric conversion section to another one of the floating diffusion regions,
in which the outer edge shape of the pixel is a geometric shape including at least four or more sides in plan view, and
a vertical gate electrode of the first transfer transistor and a vertical gate electrode of the second transfer transistor are arranged along a diagonal line connecting two corner portions of the pixels across the intra-pixel separation section in the plan view.
   (2)

The photodetection device according to (1), in which
one of the plurality of floating diffusion regions is arranged between the vertical gate electrode of the first transfer transistor and the inter-pixel separation section, and another one of the floating diffusion regions is arranged between the vertical gate electrode of the second transfer transistor and the inter-pixel separation section.
   (3)

The photodetection device according to (2), in which
one of the plurality of floating diffusion regions is arranged between the vertical gate electrode of the first transfer transistor and a first corner portion of the inter-pixel separation section, and another one of the floating diffusion regions is arranged between the vertical gate electrode of the second transfer transistor and a second corner portion of the inter-pixel separation section.
   (4)

The photodetection device according to (2), in which
one of the plurality of floating diffusion regions is arranged between the vertical gate electrode of the first transfer transistor and a first side portion of the inter-pixel separation section, and another one of the floating diffusion regions is arranged between the vertical gate electrode of the second transfer transistor and a second side portion of the inter-pixel separation section.
   (5)

The photodetection device according to (1), in which
each of the plurality of pixels includes a contact of at least one well region provided on the element surface of the semiconductor layer.
   (6)

The photodetection device according to (1), in which
at least a part of the plurality of pixels arranges the floating diffusion region at a corner portion of adjacent pixels with the inter-pixel separation section interposed therebetween.
   (7)

The photodetection device according to (5), in which
at least a part of the plurality of pixels is configured to:
arrange the floating diffusion region at a corner portion of adjacent pixels with the inter-pixel separation section interposed therebetween, and
arrange the contact of the well region at a corner portion of adjacent pixels with the inter-pixel separation section interposed therebetween.
   (8)

The photodetection device according to (1), in which
at least a part of the plurality of pixels includes:
a first pixel in which the intra-pixel separation section extends in a first direction; and
a second pixel adjacent to the first pixel and having the intra-pixel separation section extending in a second direction orthogonal to the first direction.
   (9)

The photodetection device according to (5), in which the contact of the well region is arranged on an element surface side of the intra-pixel separation section at a center of the pixel.

(10)

The photodetection device according to (1), in which
each of the plurality of pixels includes at least one pixel transistor that processes the charge generated by the first photoelectric conversion section and the second photoelectric conversion section.
   (11)

The photodetection device according to (10), in which
one of the plurality of floating diffusion regions is arranged between the vertical gate electrode of the first transfer transistor and the intra-pixel separation section, and another one of the floating diffusion regions is arranged between the vertical gate electrode of the second transfer transistor and the intra-pixel separation section.
   (12)

The photodetection device according to (10), in which
one of the plurality of floating diffusion regions is arranged between the vertical gate electrode of the first transfer transistor and the inter-pixel separation section, and another one of the floating diffusion regions is arranged between the vertical gate electrode of the second transfer transistor and the inter-pixel separation section.
   (13)

The photodetection device according to (1), in which the intra-pixel separation section is formed by the full trench at least a part of which extends from a side portion of the inter-pixel separation section.

(14)

The photodetection device according to (13), in which
one of the plurality of floating diffusion regions is arranged between the vertical gate electrode of the first transfer transistor and a first corner portion of the inter-pixel separation section, and another one of the floating diffusion regions is arranged between the vertical gate electrode of the second transfer transistor and a second corner portion of the inter-pixel separation section.
   (15)

The photodetection device according to (13), in which
at least a part of the plurality of pixels arranges the floating diffusion region at a corner portion of adjacent pixels with the inter-pixel separation section interposed therebetween.
   (16)

The photodetection device according to (13), in which
at least a part of the plurality of pixels includes:
a first pixel in which the intra-pixel separation section extends in a first direction; and
a second pixel adjacent to the first pixel and having the intra-pixel separation section extending in a second direction orthogonal to the first direction.
   (17)

The photodetection device according to (13), in which
one of the plurality of floating diffusion regions is arranged between the vertical gate electrode of the first transfer transistor and the full trench of the intra-pixel separation section, and another one of the floating diffusion regions is arranged between the vertical gate electrode of the second transfer transistor and the full trench of the intra-pixel separation section.
   (18)

An electronic apparatus including
a photodetection device including
a semiconductor layer including a plurality of pixels arranged in a matrix and having a light incident surface on which light is incident on the pixels,
each of the plurality of pixels including:
an inter-pixel separation section that defines an outer edge shape of the pixel, is formed by a full trench extending from a light incident surface of the semiconductor layer to an element surface on a side opposite to the light incident surface, and insulates and shields the pixel adjacent;
an intra-pixel separation section that separates the pixel into two;
a first photoelectric conversion section and a second photoelectric conversion section that are provided adjacent to each other via the intra-pixel separation section in plan view and generate a charge of an amount corresponding to light incident on the light incident surface, respectively;
a plurality of floating diffusion regions provided on the element surface of the semiconductor layer and temporarily accumulating the charge;
a first transfer transistor that transfers the charge generated by the first photoelectric conversion section to one of the plurality of floating diffusion regions; and
a second transfer transistor that transfers the charge generated by the second photoelectric conversion section to another one of the floating diffusion regions,
in which the outer edge shape of the pixel is a geometric shape including at least four or more sides in plan view, and
a vertical gate electrode of the first transfer transistor and a vertical gate electrode of the second transfer transistor are arranged along a diagonal line connecting two corner portions of the pixels across the intra-pixel separation section in the plan view.

### REFERENCE SIGNS LIST

1, 1A, 1B, 1C, 1D, 1E, 1F, 1G, 1H, 1I, 1J, 1K, 1L, 1M, 1N, 10, 1P, 1Q, 1R, 1S, 1T, 1U, 1V, 1W, 1X Photodetection device
2 Semiconductor chip
2A Pixel region
2B Peripheral region
3(3-1, 3-2, 3-3, 3-4), 3, 3A, 3B, 3C, 3D, 3E, 3F, 3G, 3H, 3I, 3J, 3K, 3L, 3M, 3N, 3O, 3P, 3Q, 3R, 3S, 3T, 3U, 3V, 3W, 3X Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
14 Bonding pad
15 Readout circuit
20 Semiconductor layer
20a Active region
21 Photoelectric conversion unit
22 Inter-pixel separation section
22a1, 22a2, 22a3, 22a4 Corner portion
22b1, 22b2 Side portion
23L First photoelectric conversion section
23R Second photoelectric conversion section
24L First transfer transistor
24R Second transfer transistor
25L First charge accumulation region (FD1)
25R Second charge accumulation region (FD2)
30 Multilayer wiring layer
31 Interlayer insulating film
32 Wiring
41 Support substrate
42 Color filter
43 On-chip lens layer
43a On-chip lens
50, 51 Intra-pixel separation section
60 Contact of well region
71, 72 Separation region
2201 Imaging device
2202 Optical system
2203 Shutter device
2204 Solid-state imaging element
2205 Control circuit
2206 Signal processing circuit
2207 Monitor
2208 Memory
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101 to 12105 Imaging section
12111 to 12114 Imaging range

What is claimed is:

1. A photodetection device, comprising:
a semiconductor layer including a plurality of pixels arranged in a matrix and having a light incident surface on which light is incident on the pixels,
each of the plurality of pixels including:
an inter-pixel separation section that defines an outer edge shape of the pixel, is formed by a full trench extending from a light incident surface of the semiconductor layer to an element surface on a side opposite to the light incident surface, and insulates and shields the pixel adjacent;
an intra-pixel separation section that separates the pixel into two;
a first photoelectric conversion section and a second photoelectric conversion section that are provided adjacent to each other via the intra-pixel separation section in plan view and generate a charge of an amount corresponding to light incident on the light incident surface, respectively;
a plurality of floating diffusion regions provided on the element surface of the semiconductor layer and temporarily accumulating the charge;
a first transfer transistor that transfers the charge generated by the first photoelectric conversion section to one of the plurality of floating diffusion regions; and
a second transfer transistor that transfers the charge generated by the second photoelectric conversion section to another one of the floating diffusion regions,
wherein the outer edge shape of the pixel is a geometric shape including at least four or more sides in plan view, and
a vertical gate electrode of the first transfer transistor and a vertical gate electrode of the second transfer transistor are arranged along a diagonal line connecting two corner portions of the pixels across the intra-pixel separation section in the plan view.

2. The photodetection device according to claim 1, wherein
one of the plurality of floating diffusion regions is arranged between the vertical gate electrode of the first transfer transistor and the inter-pixel separation section, and another one of the floating diffusion regions is arranged between the vertical gate electrode of the second transfer transistor and the inter-pixel separation section.

3. The photodetection device according to claim 2, wherein
one of the plurality of floating diffusion regions is arranged between the vertical gate electrode of the first transfer transistor and a first corner portion of the inter-pixel separation section, and another one of the floating diffusion regions is arranged between the vertical gate electrode of the second transfer transistor and a second corner portion of the inter-pixel separation section.

4. The photodetection device according to claim 2, wherein
one of the plurality of floating diffusion regions is arranged between the vertical gate electrode of the first transfer transistor and a first side portion of the inter-pixel separation section, and another one of the floating diffusion regions is arranged between the vertical gate electrode of the second transfer transistor and a second side portion of the inter-pixel separation section.

5. The photodetection device according to claim 1, wherein
each of the plurality of pixels includes a contact of at least one well region provided on the element surface of the semiconductor layer.

6. The photodetection device according to claim 1, wherein
at least a part of the plurality of pixels arranges the floating diffusion region at a corner portion of adjacent pixels with the inter-pixel separation section interposed therebetween.

7. The photodetection device according to claim 5, wherein
at least a part of the plurality of pixels is configured to:
arrange the floating diffusion region at a corner portion of adjacent pixels with the inter-pixel separation section interposed therebetween, and
arrange the contact of the well region at a corner portion of adjacent pixels with the inter-pixel separation section interposed therebetween.

8. The photodetection device according to claim 1, wherein
at least a part of the plurality of pixels includes:
a first pixel in which the intra-pixel separation section extends in a first direction; and
a second pixel adjacent to the first pixel and having the intra-pixel separation section extending in a second direction orthogonal to the first direction.

9. The photodetection device according to claim 5, wherein the contact of the well region is arranged on an element surface side of the intra-pixel separation section at a center of the pixel.

10. The photodetection device according to claim 1, wherein
each of the plurality of pixels includes at least one pixel transistor that processes the charge generated by the first photoelectric conversion section and the second photoelectric conversion section.

11. The photodetection device according to claim 10, wherein
one of the plurality of floating diffusion regions is arranged between the vertical gate electrode of the first transfer transistor and the intra-pixel separation section, and another one of the floating diffusion regions is arranged between the vertical gate electrode of the second transfer transistor and the intra-pixel separation section.

12. The photodetection device according to claim 10, wherein
one of the plurality of floating diffusion regions is arranged between the vertical gate electrode of the first transfer transistor and the inter-pixel separation section, and another one of the floating diffusion regions is arranged between the vertical gate electrode of the second transfer transistor and the inter-pixel separation section.

13. The photodetection device according to claim 1, wherein the intra-pixel separation section is formed by the full trench at least a part of which extends from a side portion of the inter-pixel separation section.

14. The photodetection device according to claim 13, wherein
one of the plurality of floating diffusion regions is arranged between the vertical gate electrode of the first transfer transistor and a first corner portion of the inter-pixel separation section, and another one of the floating diffusion regions is arranged between the vertical gate electrode of the second transfer transistor and a second corner portion of the inter-pixel separation section.

15. The photodetection device according to claim 13, wherein
at least a part of the plurality of pixels arranges the floating diffusion region at a corner portion of adjacent pixels with the inter-pixel separation section interposed therebetween.

16. The photodetection device according to claim 13, wherein
at least a part of the plurality of pixels includes:
a first pixel in which the intra-pixel separation section extends in a first direction; and
a second pixel adjacent to the first pixel and having the intra-pixel separation section extending in a second direction orthogonal to the first direction.

17. The photodetection device according to claim 13, wherein
one of the plurality of floating diffusion regions is arranged between the vertical gate electrode of the first transfer transistor and the full trench of the intra-pixel separation section, and another one of the floating diffusion regions is arranged between the vertical gate electrode of the second transfer transistor and the full trench of the intra-pixel separation section.

18. An electronic apparatus, comprising
a photodetection device comprising
a semiconductor layer including a plurality of pixels arranged in a matrix and having a light incident surface on which light is incident on the pixels,
each of the plurality of pixels including:
an inter-pixel separation section that defines an outer edge shape of the pixel, is formed by a full trench extending from a light incident surface of the semiconductor layer to an element surface on a side opposite to the light incident surface, and insulates and shields the pixel adjacent;
an intra-pixel separation section that separates the pixel into two;
a first photoelectric conversion section and a second photoelectric conversion section that are provided adjacent to each other via the intra-pixel separation section in plan view and generate a charge of an amount corresponding to light incident on the light incident surface, respectively;
a plurality of floating diffusion regions provided on the element surface of the semiconductor layer and temporarily accumulating the charge;
a first transfer transistor that transfers the charge generated by the first photoelectric conversion section to one of the plurality of floating diffusion regions; and
a second transfer transistor that transfers the charge generated by the second photoelectric conversion section to another one of the floating diffusion regions,
wherein the outer edge shape of the pixel is a geometric shape including at least four or more sides in plan view, and
a vertical gate electrode of the first transfer transistor and a vertical gate electrode of the second transfer transistor are arranged along a diagonal line connecting two corner portions of the pixels across the intra-pixel separation section in the plan view.
